(19) United States
(12) Patent Application Publication
(10) Pub. No.: US 2026/0040737 A1
(43) Pub. Date: Feb. 5, 2026

(54) PICK-UP CONTROL METHOD AND TRANSFER DEVICE FOR LIGHT-EMITTING ELEMENT CHIP

(71) Applicant: LG Display Co., Ltd., Seoul (KR)

(72) Inventor: Se Jun YOON, Paju-si (KR)

(73) Assignee: LG Display Co., Ltd., Seoul (KR)

(21) Appl. No.: 19/253,466

(22) Filed: Jun. 27, 2025

(30) Foreign Application Priority Data
Jul. 30, 2024 (KR) 10-2024-0100623

(51) Int. Cl. H10H 29/02; H01L 21/66

(52) U.S. Cl. CPC H10H 29/02; H01L 22/10

(57) ABSTRACT

A pickup control method and a transfer device of a light-emitting element chip are discussed. The pickup control method can include a first operation of loading stamps on a transfer head, transporting the transfer head to a first substrate, and picking up light-emitting element chips with the stamps, a second operation of transporting the transfer head along with the stamps that pick up the light-emitting element chips to a second substrate and checking pickup states of the light-emitting element chips transported to the second substrate using an image detector located below the transfer head, and a third operation of transporting the transfer head along with the stamps that pick up the light-emitting element chips toward a chip removal system when a pickup failure is detected from the light-emitting element chips as a result of analyzing an image captured by the image detector.

### CROSS-REFERENCE TO RELATED APPLICATION

This application claims priority to Korean Patent Application No. 10-2024-0100623, filed in the Republic of Korea on Jul. 30, 2024, the entire contents of which are hereby expressly incorporated by reference into the present application.

### BACKGROUND

### Technical Field

The present disclosure relates to a pickup control method and a transfer device for a light-emitting element chip, and more specifically, for example, without limitation, to a pickup control method and a transfer device for a light-emitting element chip, which allow the probability of damage to a stamp to be reduced and the use time of the stamp to be increased so that the time for unnecessarily replacing stamps is reduced.

### Discussion of the Related Art

Examples of a display device include organic light-emitting diode (OLED) display devices that emit light by itself, liquid crystal display (LCD) devices that require separate light sources, etc.

Recently, display devices including light-emitting diodes (LEDs) have been attracting attention as next-generation display devices. Since an LED is formed of an inorganic material rather than an organic material, the display devices including the LEDs have a faster turn-on speed, better luminous efficiency, and higher luminance images than LCD devices or OLED display devices.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventor has realized that in the related art, a damage to a stamp can occur in a process of forming a micro light-emitting element of a display device. Accordingly, a process of transferring a micro light-emitting element, which is performed to manufacture a display device using a micro light-emitting element, can use a method of transferring a plurality of micro light-emitting element chips onto a panel substrate on which a driving circuit is formed using a stamp by which the plurality of micro light-emitting element chips are picked up.

Example embodiments of the present disclosure are directed to providing a pickup control method and a transfer device for a light-emitting element chip, which allow the probability of damage to a stamp to be reduced and the use time of the stamp to be increased so that the time for unnecessarily replacing stamps is reduced.

A pickup control method for a light-emitting element chip according to one example embodiment of the present disclosure can comprise a first operation of loading a plurality of stamps on a transfer head, transporting the transfer head to a first substrate, and picking up a plurality of light-emitting element chips with the stamps; a second operation of transporting the transfer head along with the stamps that pick up the light-emitting element chips to a second substrate and checking pickup states of the light-emitting element chips transported to the second substrate using a camera located below the transfer head; a third operation of transporting the transfer head along with the stamps that pick up the light-emitting element chips toward a chip removal system when a pickup failure is detected from the light-emitting element chips as a result of analyzing an image captured by the camera; and a fourth operation of blowing ionized air toward the stamps from the chip removal system and removing the light-emitting element chips from the stamps in a non-contact manner.

A transfer device according to another example embodiment of the present disclosure can comprise a stamp that picks up a plurality of light-emitting element chips located on a first substrate and transfers the plurality of light-emitting element chips onto a second substrate; a transfer head that transports the stamp to perform transferring and picking up; an image detector that checks pickup states of the plurality of picked-up light-emitting element chips; and a chip removal system that removes the light-emitting element chips when a pickup failure is detected from the light-emitting element chips.

Objects of example embodiments of the present disclosure are not limited to the above-described objects, and other objects that are not mentioned will be able to be clearly understood by those skilled in the art from the following description.

### BRIEF DESCRIPTION OF THE DRAWINGS

The above and other objects, features, and advantages of the present disclosure will become more apparent to those of ordinary skill in the art by describing example embodiments thereof in detail with reference to the accompanying drawings, in which:

FIG. 1 is an exploded perspective view of a display device according to one example embodiment of the present disclosure;

FIG. 2 is a plan view of a display device according to one example embodiment of the present disclosure;

FIG. 3 is an enlarged plan view of a connection structure of a display device according to one example embodiment of the present disclosure;

FIG. 4 is a diagram illustrating a circuit structure according to an example embodiment of the present disclosure.

FIG. 5 is an enlarged view of a display device according to one example embodiment of the present disclosure;

FIG. 6 is a plan view of a display device according to an example embodiment of the present disclosure.

FIG. 7 is a plan view of a display device according to an example embodiment of the present disclosure.

FIG. 8 is a cross-sectional view of a display device according to an example embodiment of the present disclosure.

FIG. 9 is an enlarged cross-sectional view of a display device according to an example embodiment of the present disclosure.

FIG. 10 is a perspective view illustrating a state in which a light-emitting element chip of a display device is picked up according to an example embodiment of the present disclosure;

FIG. 11 is a perspective view illustrating a state in which the light-emitting element chip of the display device is transferred according to the example embodiment of the present disclosure;

FIG. 12 is a plan view illustrating a transfer device in the display device according to the example embodiment of the present disclosure;

FIG. 13 is a cross-sectional view illustrating a chip removal system of the transfer device in the display device according to the example embodiment of the present disclosure;

FIG. 14 is a view illustrating a static electricity remover of the chip removal system of the transfer device in the display device according to the example embodiment of the present disclosure;

FIG. 15 is a view illustrating an ion generator of the static electricity remover of the chip removal system of the transfer device in the display device according to the example embodiment of the present disclosure;

FIG. 16 is a view illustrating an ion generator of the static electricity remover of the chip removal system of the transfer device in the display device according to the example embodiment of the present disclosure;

FIG. 17 is a perspective view illustrating a stamp and a light-emitting element chip collector of the chip removal system of the transfer device in the display device according to the example embodiment of the present disclosure;

FIG. 18 is a cross-sectional view illustrating the light-emitting element chip collector of the chip removal system of the transfer device in the display device according to the example embodiment of the present disclosure;

FIG. 19 is a perspective view illustrating a defective light-emitting element suction unit of the chip removal system of the transfer device in the display device according to the example embodiment of the present disclosure;

FIG. 20 is a cross-sectional view illustrating a light-emitting element chip collector of the transfer device in the display device according to the example embodiment of the present disclosure;

FIG. 21 is a flowchart illustrating a normal chip transfer process of the transfer device in the display device according to the example embodiment of the present disclosure; and

FIG. 22A FIG. 22B and FIG. 22C are cross-sectional views illustrating a defective chip removal process of the transfer device in the display device according to the example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF EXAMPLE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

The advantages and features of the present disclosure, and methods of achieving them will become apparent upon reference to the embodiments described in detail below in conjunction with the accompanying drawings. However, the present disclosure is not limited to the following embodiments disclosed herein, but can be implemented in various different forms; rather, the present embodiments are provided to make the disclosure of the present disclosure complete and to enable those skilled in the art to fully comprehend the scope of the present disclosure.

The shapes, sizes, dimensions (e.g., length, width, height, thickness, radius, diameter, area, etc.), ratios, angles, numbers, and the like of elements shown in the drawings to illustrate embodiments of the present disclosure are merely illustrative and are not intended to be limiting. Identical reference numerals can designate identical components throughout the description. Further, in describing the present disclosure, detailed descriptions of related known technologies can be omitted so as not to obscure the essence of the present disclosure.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms such as, “include,” “have,” “comprise,” “contain,” “constitute,” “make up of,” “formed of,” and “consist of” as used herein are generally intended to allow for the addition of other components, unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on”, “above”, “over”, “below”, “under”, “beside”, “beneath”, “near”, “close to,” “adjacent to”, “on a side of”, “next” describes the positional relationship of two parts, one or more other parts can be located between the two parts, unless “immediately,” “directly,” or “near to” is used.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

When describing a temporal relationship, “after,” “following,” “next to,” or “before” describes a temporal antecedent or consequent relationship, which may not be continuous unless “immediately” or “directly” is used.

The terms such as ‘first,’ ‘second,’ and so on are used to describe various components, but these components are not limited by these terms. These terms are used only to distinguish one component from another and may not define order or sequence. Therefore, the first component referred to below can be a second component within the technical spirit of the present disclosure.

Terms such as first, second, A, B, (a), or (b) can be used to describe elements of the present disclosure. Such terms are intended only to distinguish one component from another and are not intended to define the nature, sequence, order, or number of such components.

When a component is described as being “connected,” “coupled,”, “accessed,” or “attached” to another component, it is to be understood that the component can be directly connected, coupled, accessed, or attached to the other component, but that there can also be other components interposed between the respective components which can be indirectly connected, coupled, accessed, or attached, unless specifically stated otherwise.

When a component is described as being “in contacted” or “overlapped” with another component, it is to be understood that the component can be in direct contacted or overlap with the other component, but that there can also be other components “interposed” between the respective components which can be in direct or indirect contacted or overlap with, unless specifically stated otherwise.

It should be understood that the term “at least one” includes all possible combinations of one or more related components. For example, the meaning of “at least one of the first, second, and third components” can be understood to include not only the first, second, or third component, but also any combination of two or more of the first, second, and third components.

The terms the first direction, the second direction, the third direction, the X-axis direction, the Y-axis direction, and the Z-axis direction are not to be interpreted solely as a geometric relationship in which the relationship to one another is perpendicular, but can refer to a broader range of orientations in which the configurations of the present disclosure can function.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto. Further, the term “can” fully encompasses all the meanings and coverages of the term “may” and vice versa.

Each of the features of various example embodiments of the present disclosure can be coupled or combined with one another in whole or in part, and can be technologically interlocked and operated in various ways, and each of the example embodiments can be carried out independently or in conjunction with one another.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode can be the drain electrode, and the drain electrode can be the source electrode. Further, the source electrode in any one aspect of the present disclosure can be the drain electrode in another aspect of the present disclosure, and the drain electrode in any one aspect of the present disclosure can be the source electrode in another aspect of the present disclosure.

Hereinafter, various example embodiments of the present disclosure will be described in detail with reference to the accompanying drawings. All the components of each display device according to all embodiments of the present disclosure are operatively coupled and configured.

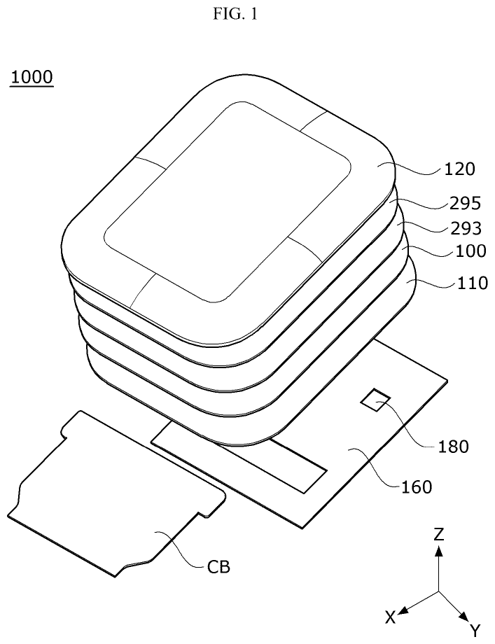

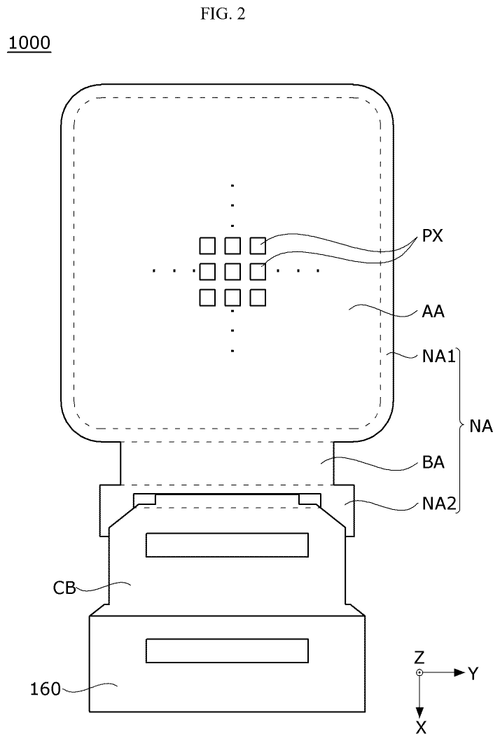

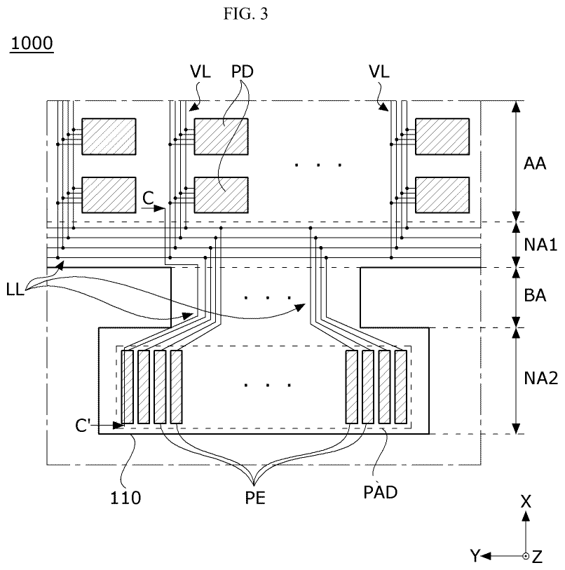

FIG. 1 is an exploded perspective view of a display device according to one example embodiment of the present disclosure. FIG. 2 is a plan view of a display device according to one example embodiment of the present disclosure. FIG. 3 is an enlarged plan view of a connection structure of a display device according to one example embodiment of the present disclosure.

Referring to FIGS. 1 to 3, a display device 1000 according to one example embodiment of the present disclosure can include a display panel 100, a polarizing layer 293, an adhesive layer 295, a cover member 120, a support substrate 110, a flexible circuit board CB, and a printed circuit board 160.

For example, the display device 1000 can include a substrate 110. The substrate 110 can be a member that supports other components of the display device 1000. The substrate 110 can be made of an insulating material. For example, the substrate 110 can be made of glass, resin, or the like. Additionally, the substrate 110 can be made of a material having flexibility. For example, the substrate can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. For example, the substrate 110 can be a film made of a flexible plastic material film such as polyimide (PI) or the like. However, the example embodiments of the present disclosure are not limited thereto.

The display panel 100 can have a width in a Y-axis direction, a length in a X-axis direction, and a thickness in a Z-axis direction, but not limited thereto. For example, the display panel 100 can have a width in an X-axis direction, a length in a Y-axis direction, and a thickness in a Z-axis direction. The X-axis direction and the Y-axis direction can intersect each other on the plane of the display panel 100. For example, the X-axis direction and the Y-axis direction can be orthogonal to each other, but not limited thereto.

The display panel 100 can implement information, video, and/or an image provided to a user. For example, the display panel 100 can include a display area AA (or active area) and a non-display area NA (or non-active area). For example, the substrate 110 can include the display area AA and the non-display area NA. The display area AA and non-display area NA are not limited to being described only with respect to the substrate 110 but can be described throughout the entire display device 1000.

The display area AA can be an area in which an image is displayed. The display area AA can include a plurality of pixels PX. Each of the plurality of pixels PX can be composed of a plurality of sub-pixels. Each of the plurality of subpixels is a minimum unit which configures the display region and n subpixels form one pixel. Each of the plurality of subpixels can emit light having different wavelengths from each other. The plurality of subpixels can include first to third subpixels which emit different color light from each other. For example, the sub-pixels can include red, green, and blue sub-pixels. Meanwhile, the sub-pixels can also include white sub-pixel. The plurality of subpixels can be variously modified in colors and configurations, as necessary. However, the present disclosure is not limited thereto.

For example, the plurality of subpixels can include red, green, and blue subpixels, in which the red, green, and blue subpixels can be disposed in a repeated manner. Alternatively, the plurality of subpixels can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

A plurality of micro-LEDs can be respectively arranged in the plurality of sub-pixels. The plurality of micro-LEDs can be configured differently depending on the type of display device 1000.

The non-display area NA can be an area in which no image is displayed. The non-display region NA can be placed outside the display region AA. For example, the non-display region NA can be an area adjacent to the display region DA. Further, the non-display region NA can be an area disposed adjacent to the display region AA and configured to surround the display region DA. Various wires and circuits for driving the plurality of pixels PX of the display area AA can be positioned in the non-display area NA. For example, in the non-display area NA, various wires and driving circuits can be mounted, and a pad portion PAD to which an integrated circuit, a printed circuit, and the like are connected can be provided, but the example embodiments of the present disclosure are not limited thereto.

For example, the driving circuit can be a data driving circuit and/or a gate driving circuit, but the example embodiments of the present disclosure are not limited thereto. Wires through which a control signal for controlling the driving circuits is supplied can be provided. For example, the control signal can include various timing signals including a clock signal, an input data enable signal, and synchronization signals (for example, a horizontal synchronization signal and a vertical synchronization signal), but the example embodiments of the present disclosure are not limited thereto. Here, the horizontal synchronization signal is a signal representing a time taken to display one horizontal line of a screen and the vertical synchronization signal is a signal representing a time taken to display a screen of one frame. The input data enable signal can correspond to a signal indicating a period for which a data voltage is supplied to the pixel. The control signal can be received through the pad portion PAD. For example, link wires LL for transmitting signals can be positioned in the non-display area NA. For example, the pad portion PAD can be connected to driving components such as the flexible circuit board CB and the printed circuit board 160.

The non-display area NA can include a first non-display area NA1, a bending area BA, and a second non-display area NA2. For example, the first non-display area NA1 can be an area that surrounds at least a portion of the display area AA. The bending area BA can be an area extending from at least one of the plurality of sides of the first non-display area NA1, and can be a bendable area. The second non-display area NA2 can be an area extending from the bending area BA, and the pad portion PAD can be positioned in the second non-display area NA2. For example, the bending area BA can be in a bent state, and the remaining area of the substrate 110, excluding the bending area BA, can be in a flat state. In this case, as the bending area BA is in a bent state, the second non-display area NA2 can be positioned on the rear surface of the display area AA. However, the example embodiments of the present disclosure are not limited thereto.

The display area AA of the substrate 110 or the display device 1000 can be configured in various shapes depending on the design of the display device 1000. For example, the display area AA can be configured in a rectangular shape with four rounded corners, but the example embodiments of the present disclosure are not limited thereto. In another example, the display area AA can be configured in a rectangular shape with four right-angled corners, a circular shape, or the like, but the example embodiments of the present disclosure are not limited thereto.

According to the present disclosure, the width of the second non-display area NA2 in which a plurality of pad electrodes PE are arranged can be greater than the width of the bending area BA in which only the plurality of link wires LL are arranged. Additionally, the width of the display area AA in which the plurality of sub-pixels are arranged can be greater than the width of the bending area BA in which only the plurality of link wires LL are arranged. In the drawings, the width of the bending area BA is illustrated as being smaller than that of other areas of the substrate 110. However, the shape of the substrate 110 including the bending area BA is merely example, and the example embodiments of the present disclosure are not limited thereto.

Referring to FIG. 2, in the display device according to an example embodiment of the present disclosure, a display area AA in which a plurality of pixels PX are disposed and a first non-display area NA1 surrounding the display area AA can be disposed.

Referring to FIG. 3, a plurality of pixel driving circuits PD can be arranged in the display area AA. The plurality of pixel driving circuits PD can be circuits for driving the micro-LEDs of the plurality of sub-pixels. Each of the plurality of pixel driving circuits PD can include a plurality of transistors including a driving transistor, a storage capacitor, and the like and can supply a control signal, power, and a driving current to the micro-LEDs of the plurality of sub-pixel to control the light emission operation of the plurality of micro-LEDs. For example, the pixel driving circuit PD can include a power wire and a signal wire for controlling the on/off state and/or light emission time of the micro-LED. For example, the plurality of pixel driving circuits PD can be a driving driver manufactured using a metal-oxide-silicon field effect transistor (MOSFET) fabrication process on a semiconductor substrate, but the example embodiments of the present disclosure are not limited thereto. The driving driver can include the plurality of pixel driving circuits PD and can drive the plurality of sub-pixels.

For example, the pixel driving circuits PD of each of the plurality of subpixels can include a capacitor, at least one thin film transistor, and a light emitting element, such as an OLED. For example, the at least one thin film transistor can include a driving transistor, a first switching transistor, and a second switching transistor. In addition, the light emitting element can include a first electrode/a second electrode (or anode electrode, pixel electrode), an inorganic light emitting layer (or organic light emitting layer), and a second electrode/a first electrode (or cathode electrode, common electrode). However, the pixel driving circuits PD of each of the plurality of subpixels are not limited thereto, each of the plurality of subpixels can further include a compensation circuit. In this case, each of the plurality of subpixels can have various structures such as 4T2C, 5T2C, 6T1C, 6T2C, 7T1C, 7T2C, and the like.

The transistors including driving transistors and switching transistors can be implemented as a thin film transistor (TFT).

Active layers of the thin-film transistors TFTs can be formed of a semiconductor material, such as an oxide semiconductor, amorphous semiconductor, or polycrystalline semiconductor, but is not limited thereto.

The oxide semiconductor material can have an excellent effect of preventing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

Referring also to FIG. 1, the flexible circuit board CB and the printed circuit board 160 can be positioned below the display panel 100. The flexible circuit board CB and the printed circuit board 160 can be positioned on at least one edge of the display panel 100, but the example embodiments of the present disclosure are not limited thereto.

One side of the flexible circuit board CB can be attached to the display panel 100, and the other side thereof can be attached to the printed circuit board 160, but example embodiments of the present disclosure are not limited thereto. The flexible circuit board CB can be a flexible film, but example embodiments of the present disclosure are not limited thereto.

The pad portion PAD including the plurality of pad electrodes PE can be positioned in the second non-display area NA2. Driving components, including one or more flexible circuit boards (or flexible films) CB and the printed circuit board 160, can be attached or bonded to the pad portion PAD. The plurality of pad electrodes PE of the pad portion PAD can be electrically connected to the one or more flexible circuit boards (or flexible films) CB, and can transmit various signals (or power) from the printed circuit board 160 and the flexible circuit board (or flexible film) CB to the plurality of pixel driving circuits PD of display area AA.

The flexible circuit board (or flexible film) CB can be a film in which various components are arranged on a base film having flexibility. For example, a driving IC, such as a gate driver IC or a data driver IC, can be positioned on the flexible circuit board (or flexible film) CB, but the example embodiments of the present disclosure are not limited thereto.

The driving IC can be a component that processes data and a driving signal for displaying an image. The driving IC can be disposed by a method such as a chip-on-glass (COG) method, a chip-on-film (COF) method, or a tape carrier package (TCP) method depending on a method of being mounted, but example embodiments of the present disclosure are not limited thereto. The flexible circuit board (or flexible film) CB can be attached to or bonded on the plurality of pad electrodes PE through a conductive adhesive layer, but example embodiments of the present disclosure are not limited thereto.

The printed circuit board 160 can be a component electrically connected to one or more flexible circuit boards (or flexible films) CB and supplying signals to the driving IC. The printed circuit board 160 can be disposed at one side of the flexible circuit board (or flexible film) CB and electrically connected to the flexible circuit board (or flexible film) CB. Various components for supplying various signals to the driving IC can be disposed on the printed circuit board 160. For example, various components, such as a timing controller, a power supply unit, a memory, a processor, etc., can be disposed on the printed circuit board 160. For example, the printed circuit board 160 can include a power management integrated circuit (PMIC), but example embodiments of the present disclosure are not limited thereto.

The printed circuit board 160 can include at least one hole 180, but the example embodiments of the present disclosure are not limited thereto. An internal component for sensing ambient light, temperature, or the like, which can be provided to a plurality of sensors, can be positioned in a region corresponding to the at least one hole 180. For example, the internal component can include an ambient light sensor (ALS), a temperature sensor, or the like, but the example embodiments of the present disclosure are not limited thereto. For example, the hole 180 can be a transmission hole or the like, but the example embodiments of the present disclosure are not limited thereto.

The polarizing layer 293 can be positioned on the display panel 100. The polarizing layer 293 can prevent or reduce light generated from an external light source from entering the interior of the display panel 100 and affecting the micro-LEDs or the like.

The cover member 120 can be positioned on the polarizing layer 293. The cover member 120 can be a member for protecting the display panel 100. The adhesive layer 295 can be positioned between the polarizing layer 293 and the cover member 120. The cover member 120 can be attached to the display panel 100 by using the adhesive layer 295. The adhesive layer 295 can include an optically clear adhesive (OCA), an optically clear resin (OCR), a pressure sensitive adhesive (PSA), or the like, but the example embodiments of the present disclosure are not limited thereto.

The support substrate 110 can be positioned between the display panel 100 and the printed circuit board 160. The support substrate 110 can reinforce the rigidity of the display panel 100. The support substrate 110 can be a back plate, but the example embodiments of the present disclosure are not limited thereto.

Referring to FIGS. 1 to 3, the plurality of link wires LL can be arranged in the first and second non-display areas NA1 and NA2. The plurality of link wires LL can be wires for transmitting various signals from the one or more flexible circuit boards (or flexible films) CB and the printed circuit board 160 to the display area AA. The plurality of link wires LL can extend from the plurality of pad electrodes PE of the second non-display area NA2 toward the bending area BA and the first non-display area NA1, and can be electrically connected to a plurality of driving wires VL of the display area AA.

The plurality of pixel driving circuits PD can be driven by receiving signals from one or more flexible circuit boards (or flexible films) CB and the printed circuit board 160 through the driving wiring VL in the display area AA and the link wiring LL in the non-display area NA.

For example, a plurality of driving wires VL can be wires for transmitting a signal output from the flexible circuit board (or flexible film) CB and the printed circuit board 160 together with a plurality of link wires LL to a plurality of pixel driving circuits PD. A plurality of driving wires VL can be disposed in the display area AA and electrically connected to each of a plurality of pixel driving circuits PD. A plurality of driving wires VL can extend from the display area AA toward the non-display area NA and can be electrically connected to a plurality of link wires LL.

Therefore, the signal output from the flexible circuit board (or flexible film) CB and the printed circuit board 160 can be transmitted to each of the plurality of pixel driving circuits PD through the plurality of link wires LL and the plurality of driving wires VL.

As the bending area BA is bent, a portion of the plurality of link wires LL can also be bent together. Stress can be concentrated on a portion of the bent link wires LL, thereby causing cracks in the link wires LL. Accordingly, the plurality of link wires LL can be formed of a highly flexible conductive material to reduce cracks when the bending area BA is bent. For example, the plurality of link wires LL can be formed of a highly flexible conductive material, such as gold (Au), silver (Ag), or aluminum (Al), but the example embodiments of the present disclosure are not limited thereto.

Additionally, the plurality of link wires LL can be formed of one of various conductive materials used in the display area AA. For example, the plurality of link wires LL can be made of molybdenum (Mo), chromium (Cr), titanium (Ti), nickel (Ni), neodymium (Nd), copper (Cu), an alloy of silver (Ag) and magnesium (Mg), or other alloys thereof, but the example embodiments of the present disclosure are not limited thereto. The plurality of link wires LL can have a multilayer structure made of various conductive materials. For example, the plurality of link wires LL can have a triple-layer structure of titanium (Ti)/aluminum (Al)/titanium (Ti), but the example embodiments of the present disclosure are not limited thereto.

A plurality of link wirings LL can be configured in various shapes to reduce stress. At least a portion of the plurality of link wirings LL disposed on the bending area BA can extend in the same direction as the extending direction of the bending area BA, or can extend in a direction different from the extending direction of the bending area BA to reduce stress. For example, when the bending area BA extends in one direction from the first non-display area NA1 to the second non-display area NA2, at least a portion of the link wiring LL disposed on the bending area BA can extend in a direction inclined to the one direction.

For another example, at least a portion of the plurality of link wires LL can be configured in various shapes. For example, at least a portion of the plurality of link wires LL disposed on the bending area BA can have a shape in which a conductive pattern having at least one of a diamond shape, a rhombus shape, a trapezoidal shape, a triangular wave shape, a sawtooth wave shape, a sinusoidal shape, a circular shape, and an omega ((2) shape is repeatedly arranged, but example embodiments of the present disclosure are not limited thereto.

Therefore, in order to minimize or reduce the stress concentrated on the plurality of link wires LL and the corresponding crack, the shape of the plurality of link wires LL can be formed in various shapes including the above-described shape, but example embodiments of the present disclosure are not limited thereto.

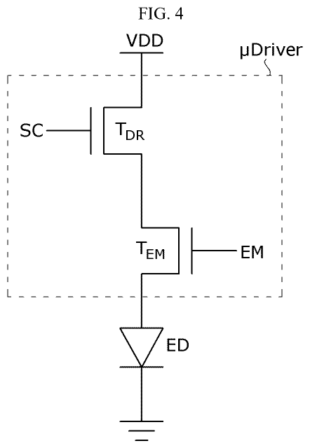

FIG. 4 is a diagram illustrating a circuit structure according to an example embodiment of the present disclosure.

Although FIG. 4 illustrates that one light emitting device ED is connected to the micro-driver, the present disclosure is not limited thereto. For example, eight light emitting devices ED can be connected to one micro-driver. For another example, 16 light emitting devices ED can be connected to one micro-driver, 32 light emitting devices ED or 64 light emitting devices ED can be connected to one micro-driver at the same time. The light emitting device ED can be a micro-light emitting device μLED.

Referring to FIG. 4, in one micro driver μDriver can include a driving transistor T_{DR} and a light emitting transistor T_{EM}, but example embodiments of the present disclosure are not limited thereto.

For example, in the driving transistor T_{DR}, a high potential power voltage VDD can be applied to the first electrode, a first electrode of the light emitting transistor T_{EM} can be connected to the second electrode, and a scan signal SC can be applied to the gate electrode. The scan signal SC applied to the gate electrode of the driving transistor T_{DR} is a direct current power source, and a fixed reference voltage Vref can be applied to each frame, but example embodiments of the present disclosure are not limited thereto.

In the light emitting transistor T_{EM}, the second electrode of the driving transistor T_{DR} is connected to the first electrode, the light emitting element ED is connected to the second electrode, and the light emitting signal EM can be applied to the gate electrode. The light emitting signal EM applied to the gate electrode of the light emitting transistor T_{EM} can be a pulse width modulation signal that changes every frame, but example embodiments of the present disclosure are not limited thereto.

In the light emitting device ED, the first electrode can be connected to the second electrode of the light emitting transistor T_{EM}, and the second electrode can be connected to the ground. For example, the first electrode can be an anode electrode and the second electrode can be a cathode electrode, but configurations of the present disclosure are not limited thereto.

Each of the driving transistor T_{DR} and the light emitting transistor T_{EM} can be an n-type transistor or a p-type transistor.

In the micro driver μDR, the driving transistor T_{DR} can be turned on by the scan signal SC applied from the timing controller T-CON, and the light emitting transistor T_{EM} can be turned on by the light emitting signal EM. As a result, the driving current is applied to the light emitting device ED via the driving transistor T_{DR} and the light emitting transistor T_{EM} by the high potential power voltage VDD applied to the first electrode of the driving transistor T_{DR}, and thus the light emitting device ED can emit light.

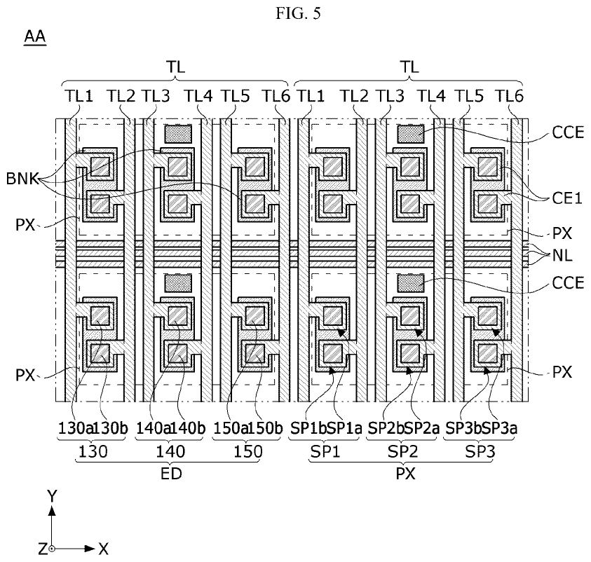

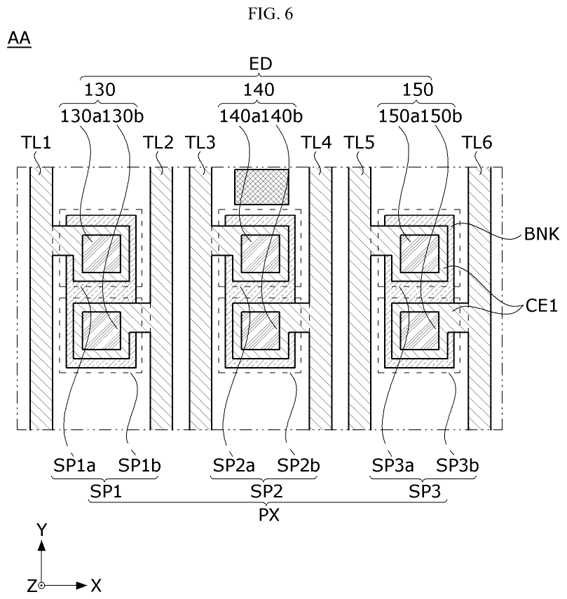

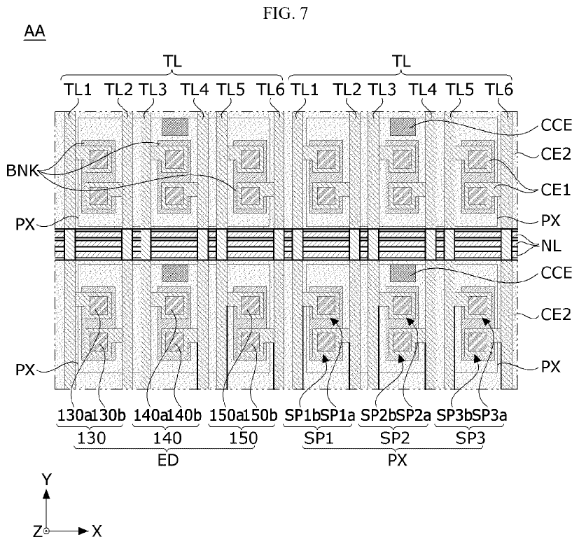

FIGS. 5 to 7 are plan views of a display device according to an example embodiment of the present disclosure. For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels.

In FIGS. 5 and 6, a plurality of signal wires TL, a plurality of communication wires NL, a plurality of first electrodes CE1, a plurality of banks BNK, and a plurality of light emitting devices ED are illustrated, but example embodiments of the present disclosure are not limited thereto. FIG. 7 is an enlarged plan view in which a plurality of second electrodes CE2 are additionally disposed in FIG. 6.

Referring to FIGS. 5 and 6, a plurality of pixels PX including a plurality of sub-pixels can be disposed in the display area AA. Each of the plurality of sub-pixels includes a light emitting device ED and can independently emit light. The plurality of sub-pixels can form a plurality of rows and a plurality of columns and can be arranged in a matrix form, but configurations of the present disclosure are not limited thereto.

A plurality of sub-pixels can include a first sub-pixel SP1, a second sub-pixel SP2, and a third sub-pixel SP3. For example, any one of the first sub-pixel SP1, the second sub-pixel SP2, and the third sub-pixel SP3 can be a red sub-pixel, the other can be a green sub-pixel, and the rest can be a blue sub-pixel. Types of a plurality of sub-pixels are examples, and example embodiments of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. The pair of first sub-pixels SP1 can include a 1-1 sub-pixel SP1a and a 1-2 sub-pixel SP1b. The pair of second sub-pixels SP2 can include a 2-1 sub-pixel SP2a and a 2-2 sub-pixel SP2b.

The pair of third sub-pixels SP3 can include a 3-1 sub-pixel SP3a and a 3-2 sub-pixel SP3b. For example, one pixel PX can include a 1-1 sub-pixel SP1a, a 1-2 sub-pixel SP1b, a 2-1 sub-pixel SP2b, a 3-1 sub-pixel SP3a, and a 3-2 sub-pixel SP3b, but example embodiments of the present disclosure are not limited thereto.

A plurality of sub-pixels constituting one pixel PX can be variously arranged. For example, in one pixel PX, a pair of first sub-pixels SP1 can be disposed in the same column, a pair of second sub-pixels SP2 can be disposed in the same column, and a pair of third sub-pixels SP3 can be disposed in the same column. The first sub-pixel SP1, the second sub-pixel SP2, and the third sub-pixel SP3 can be disposed in the same row. Alternatively, in one pixel PX, the pair of first subpixels SP1 can be disposed in the same row, the pair of second subpixels SP2 can be disposed in the same row, and the pair of third subpixels SP3 can be disposed in the same row. The first subpixel SP1, the second subpixel SP2, and the third subpixel SP3 can be disposed in the same column. The number and arrangement of a plurality of sub-pixels constituting one pixel PX are example, and configurations of the present disclosure are not limited thereto.

A plurality of signal wires TL can be disposed in a region between the plurality of sub-pixels. The plurality of signal wires TL can extend in a column direction between the plurality of sub-pixels. The plurality of signal wires TL can be wires that transmit an anode voltage from the pixel driving circuit PD to a plurality of sub-pixels. For example, the plurality of signal wires TL can be electrically connected to the plurality of pixel driving circuits PD and the first electrode CE1 of the plurality of sub-pixels.

The anode voltage output from the pixel driving circuit PD can be transferred to the first electrodes CE1 of a plurality of sub-pixels through a plurality of signal wires TL. For example, the first electrode CE1 can be an electrode electrically connected to the anode electrode 134 of the light emitting device ED. Accordingly, the anode voltage from the signal wire TL can be transferred to the anode electrode 134 of the light emitting device ED through the first electrode CE1.

Accordingly, instead of forming a plurality of transistors and storage capacitors in each of the plurality of sub-pixels, the structure of the display device 1000 can be simplified by using the pixel driving circuit PD in which the plurality of pixel circuits are integrated. Further, as circuits disposed in each of the plurality of sub-pixels are integrated in one pixel driving circuit PD, high efficiency and low power driving can be possible.

A plurality of signal wires TL can include a first signal wire TL1, a second signal wire TL2, a third signal wire TL3, a fourth signal wire TL4, a fifth signal wire TL5 and a sixth signal wire TL6. Each of the first signal wire TL1 and the second signal wire TL2 can be electrically connected to each of a pair of first sub-pixels SP1. The third signal wire TL3 and the fourth signal wire TL4 can be electrically connected to each of a pair of second sub-pixels SP2. The fifth signal wire TL5 and the sixth signal wire TL6 can be electrically connected to each of a pair of third sub-pixels SP3.

The first signal wire TL1 can be positioned on one side of the pair of first sub-pixels SP1, and the second signal wire TL2 can be positioned on the other side of the pair of first sub-pixels SP1. The first signal wire TL1 can be electrically connected to the first electrode CE1 of one, e.g., the 1-1 pair of first sub-pixels SP1. The second signal wire TL2 can be electrically connected to the first electrode CE1 of the other, e.g., the 1-2 sub-pixel SP1b, of the pair of first sub-pixels SP1.

The third signal wire TL3 can be positioned on one side of the pair of second sub-pixels SP2, and the fourth signal wire TL4 can be positioned on the other side of the pair of second sub-pixels SP2. For example, the third signal wire TL3 can be positioned adjacent to the second signal wire TL2. The third signal wire TL3 can be electrically connected to the first electrode CE1 of one, e.g., the 2-1 sub-pixel SP2a, of the pair of second sub-pixels SP2. The fourth signal wire TL4 can be electrically connected to the first electrode CE1 of the other, e.g., the 2-2 sub-pixel SP2b, of the pair of second sub-pixels SP2.

The fifth signal wire TL5 can be positioned on one side of the pair of third sub-pixels SP3, and the sixth signal wire TL6 can be positioned on the other side of the pair of third sub-pixels SP3. For example, the fifth signal wire TL5 can be positioned adjacent to the fourth signal wire TL4. The sixth signal wire TL6 can be positioned adjacent to the first signal wire TL1, which is connected to an adjacent pixel PX. The fifth signal wire TL5 can be electrically connected to the first electrode CE1 of one, e.g., the 3-1 sub-pixel SP3a, of the pair of third sub-pixels SP3. The sixth signal wire TL6 can be electrically connected to the first electrode CE1 of the other, e.g., the 3-2 sub-pixel SP3b, of the pair of third sub-pixels SP3.

As shown in FIG. 5, a first pixel includes a pair of first sub-pixels SP1, a pair of second sub-pixels SP2, and a pair of third sub-pixels SP3, wherein, the pair of first sub-pixels SP1 includes a 1-1 sub-pixel SP1a and a 1-2 sub-pixel SP1b, the pair of second sub-pixels SP2 includes a 2-1 sub-pixel SP2a and a 2-2 sub-pixel SP2b, and the pair of third sub-pixels SP3 includes a 3-1 sub-pixel SP3a and a 3-2 sub-pixel SP3b. The first signal wire TL1 can be electrically connected to the first electrode CE1 of the 1-1 sub-pixel SP1a, the second signal wire TL2 can be electrically connected to the first electrode CE1 of the 1-2 sub-pixel SP1b, the third signal wire TL3 can be electrically connected to the first electrode CE1 of the 2-1 sub-pixel SP2a, the fourth signal wire TL4 can be electrically connected to the first electrode CE1 of the 2-2 sub-pixel SP2b, the fifth signal wire TL5 can be electrically connected to the first electrode CE1 of the 3-1 sub-pixel SP3a, and the sixth signal wire TL6 can be electrically connected to the first electrode CE1 of the 3-2 sub-pixel SP3b. Meanwhile, the first signal wire TL1 connected to the first pixel is adjacent to the sixth signal wire TL6 connected to a second pixel adjacent to the first pixel. However, the present disclosure is not limited thereto.

The plurality of signal wires TL can be made of a conductive material. For example, the plurality of signal wires TL can be formed of a conductive material, such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the example embodiments of the present disclosure are not limited thereto. In another example, the plurality of signal wires TL can have a multilayer structure of a conductive material. For example, the plurality of signal wires TL can have a multilayer structure of titanium (Ti)/aluminum (Al)/titanium (Ti)/indium tin oxide (ITO), but the example embodiments of the present disclosure are not limited thereto.

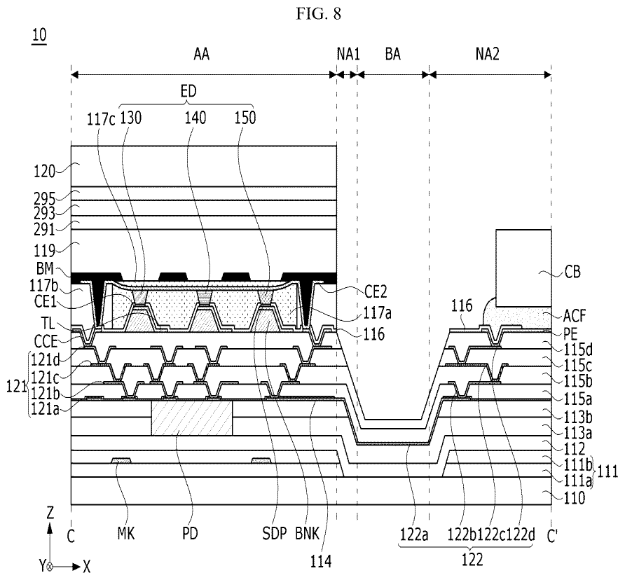

The plurality of communication wires NL can be arranged in a region between the plurality of pixels PX. The plurality of communication wires NL can extend in a row direction in the region between the plurality of pixels PX. The plurality of communication wires NL can be arranged in a region between the plurality of second electrodes (CE2 in FIG. 8), and may not overlap the plurality of second electrodes CE2. For example, the plurality of communication wires NL can be wires used for short-range communication, such as near field communication (NFC). The plurality of communication wires NL can function as an antenna. For example, the plurality of communication wires NL can be a plurality of connection wires or the like, but the example embodiments of the present disclosure are not limited thereto.

According to the present disclosure, the bank BNK can be positioned in each of the plurality of sub-pixels. The plurality of banks can be structures on which the plurality of micro-LEDs are mounted. The plurality of banks can guide the positions of the plurality of micro-LEDs ED in a transfer process for transferring the plurality of micro-LEDs ED to the display device 1000. During the transfer process of the plurality of micro-LEDs ED, the plurality of micro-LEDs ED can be transferred onto the plurality of banks BNK. The plurality of banks BNK can be bank patterns or structures, but example embodiments of present disclosure are not limited thereto.

The bank BNK of the first sub-pixel SP1, the bank BNK of the second sub-pixel SP2, and the bank BNK of the third sub-pixel SP3 can be spaced apart from each other. The bank BNK of the first sub-pixel SP1, the bank BNK of the second sub-pixel SP2, and the bank BNK of the third sub-pixel SP3 can be configured to be separated from each other. Accordingly, the banks BNK of the first sub-pixel SP1, the second sub-pixel SP2, and the third sub-pixel SP3, onto which different types of micro-LEDs ED are transferred, can be easily distinguished.

The bank BNK of the 1-1 sub-pixel SP1a and the bank BNK of the 1-2 sub-pixel SP1b can be connected to each other or can be formed to be spaced apart from each other. For example, a bank BNK of the 1-1 sub-pixel SP1a in which the same type of light emitting device ED is disposed and a bank BNK of the 1-2 sub-pixel SP1b can be connected to each other or can be spaced apart from each other or separated from each other in consideration of a design such as a transfer process requirement and the like. In addition, the bank BNK of the 3-1 sub-pixel SP3a and the bank BNK of the 3-2 sub-pixel SP3b can be connected to each other or can be formed to be spaced apart from each other.

Accordingly, the bank BNK of the pair of first sub-pixels SP1, the bank BNK of the pair of second sub-pixels SP2, and the bank BNK of the pair of third sub-pixels SP3 can be variously formed, and example embodiments of the present disclosure are not limited thereto.

The plurality of banks BNK can be formed of an opaque material (for example, black) in order to prevent light interference between adjacent pixels. In this case, the bank BNK can include a light shielding material constituted by at least one of a color pigment, organic black, or carbon, without being limited thereto.

For example, the plurality of banks BNK can be formed of an organic insulating material. The plurality of banks BNK can be configured as a single layer or a multi-layer of the organic insulating material. For example, the plurality of banks BNK can be formed of a photoresist, polyimide (PI), or acryl-based material, but the example embodiments of present disclosure are not limited thereto.

Meanwhile, the plurality of banks BNK can include an inorganic insulating material, such as silicon nitride (SiNx) or silicon oxide (SiOx), or the bank BNK can be formed of black resin. However, the present disclosure is not limited thereto.

The first electrode CE1 can be positioned in each of the plurality of sub-pixels. The first electrode CE1 can be positioned on the bank BNK. For example, the first electrodes CE1 can be positioned on the top and side surfaces of the plurality of banks BNK.

At least a portion of the first electrode CE1 can extend outside of the bank BNK and be electrically connected to the signal wire TL closest to the first electrode CE1. For example, a portion of the first electrode CE1 of the 1-1 sub-pixel SP1a can extend to one side region of the 1-1 sub-pixel SP1a and be electrically connected to the first signal wire TL1, and a portion of the first electrode CE1 of the 1-2 sub-pixel SP1b can extend to the opposite side region of the 1-2 sub-pixel SP1b and be electrically connected to the second signal wire TL2.

A portion of the first electrode CE1 of the 2-1 sub-pixel SP2a can extend to one side area of the 2-1 sub-pixel SP2a to be electrically connected to the third signal wire TL3, and a portion of the first electrode CE1 of the 2-2 sub-pixel SP2b can extend to the other side area of the 2-2 sub-pixel SP2b to be electrically connected to the fourth signal wire TL4. A portion of the first electrode CE1 of the 3-1 sub-pixel SP3a can extend to one side area of the 3-1 sub-pixel SP3a to be electrically connected to the fifth signal wire TL5, and a portion of the first electrode CE1 of the 3-2 sub-pixel SP3b can extend to the other side area of the 3-2 sub-pixel SP3b to be electrically connected to the sixth signal wire TL6.

The first electrode CE1 can be electrically connected to the anode electrode 134 of the micro-LED ED, and can transmit the anode voltage from the pixel driving circuit PD to the micro-LED ED of each of the plurality of sub-pixels through the signal wire TL. Different voltages can be applied to the respective first electrodes CE1 of the plurality of sub-pixels according to an image to be displayed. For example, different voltages can be applied to the respective first electrodes CE1 of the plurality of sub-pixels. Accordingly, the first electrode CE1 can be a pixel electrode, and the example embodiments of the present disclosure are not limited thereto.

The first electrode CE1 can be formed of a conductive material. For example, the first electrode CE1 can be formed integrally with a plurality of signal wires TLs. For example, the first electrode CE1 can be formed of the same conductive material as a plurality of signal wires TLs, but example embodiments of the present disclosure are not limited thereto. For example, the first electrode CE1 can be formed of a multi-layered structure of titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but example embodiments of the present disclosure are not limited thereto. For another example, the first electrode CE1 can be formed of a multi-layered structure of a conductive material. For example, a plurality of first electrodes CE1 can be formed of a multi-layered structure of titanium (Ti)/aluminum (Al)/titanium (Ti)/indium tin oxide (ITO), but example embodiments of the present disclosure are not limited thereto.

A light emitting element ED can be disposed in each of a plurality of sub-pixels. A plurality of light emitting elements ED can be any one of a light-emitting diode (LED) and a micro light-emitting diode (Micro LED), but example embodiments of the present disclosure are not limited thereto. A plurality of light emitting elements ED can be disposed on the bank BNK and the first electrode CE1. A plurality of light emitting elements ED can be disposed on the first electrode CE1 and can be electrically connected to the first electrode CE1. Accordingly, the light emitting element ED can emit light by receiving the anode voltage from the pixel driving circuit PD through the signal wire TL and the first electrode CE1.

The plurality of micro-LEDs ED can include a first micro-LED 130, a second micro-LED 140, and a third micro-LED 150. The first micro-LED 130 can be positioned in the first sub-pixel SP1. The second micro-LED 140 can be positioned in the second sub-pixel SP2. The third micro-LED 150 can be positioned in the third sub-pixel SP3. For example, one of the first micro-LED 130, the second micro-LED 140, and the third micro-LED 150 can be a red micro-LED, another one can be a green micro-LED, and the remaining one can be a blue micro-LED, for example, the first micro-LED 130 is a red micro-LED, the second micro-LED 140 is a green micro-LED, and the third micro-LED 150 is a blue micro-LED, but the example embodiments of the present disclosure are not limited thereto. Accordingly, by combining red light, green light, and blue light emitted from the plurality of micro-LEDs ED, various colors of light including white can be implemented. The types of the plurality of micro-LEDs ED are merely example, and the example embodiments of the present disclosure are not limited thereto.

The first light emitting device 130 can include a 1-1 light emitting device 130a disposed in the 1-1 sub-pixel SP1a and a 1-2 light emitting device 130b disposed in the 1-2 sub-pixel SP1b. The second light emitting device 140 can include a 2-1 light emitting device 140a disposed in the 2-1 sub-pixel SP2a and a 2-2 light emitting device 140b disposed in the 2-2 sub-pixel SP2b. The third light emitting device 150 can include a 3-1 light emitting device 150a disposed in the 3-1 sub-pixel SP3a and a (3-2 light emitting device 150b) disposed in the (3-2 sub-pixel SP3b).

Referring to FIGS. 5 to 7, the second electrode CE2 can be positioned in each of the plurality of sub-pixels. The second electrode CE2 can be positioned on the micro-LED ED. The second electrode CE2 can be electrically connected to the pixel driving circuit PD through the plurality of contact electrodes CCE.

For example, the second electrode CE2 can be electrically connected to a cathode electrode 135 of the micro-LED ED and can transmit a cathode voltage from the pixel driving circuit PD to the micro-LED ED. The same cathode voltage can be applied to the second electrode CE2 of each of the plurality of sub-pixels. For example, the same voltage can be applied to the second electrode CE2 of each of the plurality of sub-pixels and the cathode electrode 135 of the micro-LED ED. Accordingly, the second electrode CE2 can be a common electrode, but the example embodiments of the present disclosure are not limited thereto.

At least some of the plurality of sub-pixels can share the second electrode CE2. At least some of the second electrodes CE2 of the plurality of sub-pixels can be electrically connected to each other. As the same voltage is applied to the second electrodes CE2, the second electrodes CE2 of at least some sub-pixels can be shared. For example, the second electrodes CE2 of at least some of the plurality of pixels PX arranged in the same row can be connected to each other. For example, a single second electrode CE2 can be provided for the plurality of pixels PX. One second electrode CE2 can be provided for every n sub-pixels.

For example, some of the second electrodes CE2 of the plurality of sub-pixels can be spaced apart or separated from each other. For example, the second electrode CE2 connected to the pixels PX in an nth row and the second electrode CE2 connected to the pixels PX in an (n+1)th row can be spaced apart or separated from each other. For example, the plurality of second electrodes CE2 can be spaced apart from each other with the plurality of communication wires NL, which extend in the row direction, interposed therebetween.

The plurality of second electrodes CE2 can be made of a transparent conductive material, but the example embodiments of the present disclosure are not limited thereto. The plurality of second electrodes CE2 can be made of a transparent conductive material, allowing light emitted from the micro-LED ED to be directed upward through the second electrode CE2. For example, the second electrode CE2 can be made of a transparent conductive material such as indium tin oxide (ITO), indium zinc oxide (IZO), or indium gallium zinc oxide (IGZO), but the example embodiments of the present disclosure are not limited thereto.

The plurality of contact electrodes CCE can be arranged on the substrate 110. For example, the plurality of contact electrodes CCE can be spaced apart from the plurality of banks BNK and the plurality of signal wires TL. Each of the plurality of second electrodes CE2 can overlap at least one contact electrode CCE. For example, one second electrode CE2 can overlap the plurality of contact electrodes CCE.

For example, the plurality of contact electrodes CCE can be electrically connected to the plurality of second electrodes CE2. The plurality of contact electrodes CCE can be positioned between the substrate 110 and the plurality of second electrodes CE2 and can transmit the cathode voltage from the pixel driving circuit PD to the second electrodes CE2.

For example, when using a micro-LED as the micro-LED ED, a plurality of micro-LEDs can be formed on a wafer and transferred to the substrate 110 of the display device 1000 to fabricate the display device 1000. In the process of transferring the plurality of micro-LEDs ED having a fine size from the wafer to the substrate 110, various defects can occur. For example, in some sub-pixels, a transfer failure can occur where the micro-LED ED is not transferred, and in some other sub-pixels, a defect can occur where the micro-LED ED is transferred to an incorrect position due to an alignment error. Additionally, even if the transfer process is normally performed, the transferred micro-LED ED itself can be defective. Therefore, in the transfer process of the plurality of micro-LEDs ED, in consideration of defects, a plurality of micro-LEDs ED that emit light of the same color can be transferred onto one sub-pixel. A lighting test can be performed on the plurality of micro-LEDs ED and only one micro-LED ED that is finally determined to be normal can be used.

For example, a 1-1 micro-LED 130a and a 1-2 micro-LED 130b can be transferred together onto one pixel PX, and their defect states can be inspected. If both the 1-1 micro-LED 130a and the 1-2 micro-LED 130b are determined to be normal, only the 1-1 micro-LED 130a can be used and the 1-2 micro-LED 130b can remain unused. In another example, if, among the 1-1 micro-LED 130a and the 1-2 micro-LED 130b, only the 1-2 micro-LED 130b is determined to be normal, the 1-1 micro-LED 130a can remain unused and only the 1-2 micro-LED 130b can be used. Accordingly, even if a plurality of micro-LEDs ED that emit light of the same color are transferred onto one pixel PX, ultimately, only one of the micro-LEDs ED can be used.

Thus, in a pair of micro-LEDs ED, one can be a main (or primary) micro-LED ED, while the other can be a redundancy micro-LED ED. The redundancy micro-LED ED can be an extra micro-LED ED that is transferred in preparation for a defect in the main micro-LED ED. The redundant micro-LED can be used as a replacement in the event of a failure of the main micro-LED. Thus, by transferring both the main micro-LED ED and the redundancy micro-LED ED to one pixel PX, degradation in display quality due to defects in the main micro-LED ED or the redundancy micro-LED ED can be minimized. In addition, the main micro-LED ED and the redundancy micro-LED ED are only different in name, structures and functions thereof can be totally same, for example, the main micro-LED ED can also be called the redundancy micro-LED ED, and the redundancy micro-LED ED can also be called the main micro-LED ED, but not limited thereto.

For example, the 1-1 light emitting device 130a, the 2-1 light emitting device 140a, and the 3-1 light emitting device 150a transferred to one pixel PX can be used as the main light emitting device ED, and the 1-2 light emitting device 130b, the 2-2 light emitting device 140b, and the 3-2 light emitting device 150b can be used as the redundancy light emitting device ED.

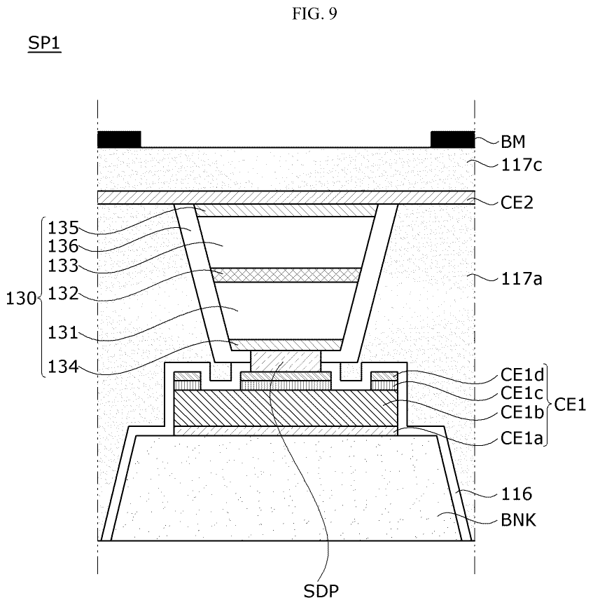

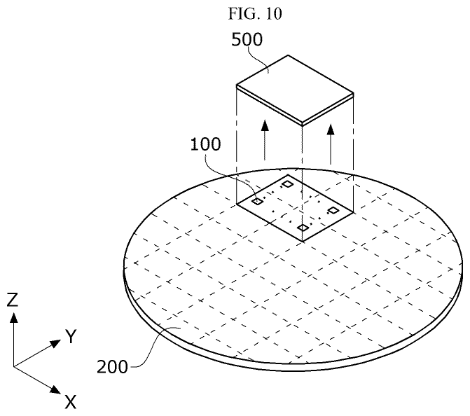

FIG. 8 is a cross-sectional view of a display device according to an example embodiment of the present disclosure. FIG. 9 is an enlarged cross-sectional view of a display device according to an example embodiment of the present disclosure. For example, FIG. 8 is a cross-sectional view of the display area AA, the first and second non-display areas NA1 and NA2, and the bending area BA.

Referring to FIG. 8, a buffer layer 111 can be disposed in the remaining area of the substrate 110 except for the bending area BA. The buffer layer 111 can include a first buffer layer 111a and a second buffer layer 111b.

The first buffer layer 111a and the second buffer layer 111b can be positioned in the display area AA, but can be not disposed on the first non-display area NA1 and the second non-display area NA2 but the example embodiments of the present disclosure are not limited thereto.

The first buffer layer 111a and the second buffer layer 111b can reduce the permeation of moisture or impurities through the substrate 110. The first buffer layer 111a and the second buffer layer 111b can be made of an inorganic insulating material. For example, the first buffer layer 111a and the second buffer layer 111b can be configured as a single layer or multi-layer of silicon oxide (SiOx) or silicon nitride (SiNx), for example, the first buffer layer 111a and the second buffer layer 111b can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the example embodiments of the present disclosure are not limited thereto. The first buffer layer 111a and the second buffer layer 111b can be excluded in accordance with the structure or properties of the display device. However, the example embodiments of the present disclosure are not limited thereto.

In addition, in order to prevent moisture permeation penetrating from the non-display area NA, the buffer layer 111 can be disposed only in the display area AA. The present disclosure is not limited thereto.

The non-display area NA can include a first non-display area NA1, a bending area BA, and a second non-display area NA2.

For example, the buffer layer 111 can be formed of a single layer or multiple layers of silicon oxide (SiOx) or silicon nitride (SiNx), which is an inorganic film material, but example embodiments of the present disclosure are not limited thereto. For example, portions of the first buffer layer 111a and the second buffer layer 111b on the bending area BA can be removed. The upper surface of the substrate 110 located in the bending area BA can be exposed from the first buffer layer 111a and the second buffer layer 111b. By removing the first buffer layer 111a and the second buffer layer 111b made of the inorganic insulating material from the bending area BA, cracks in the first buffer layer 111a and the second buffer layer 111b that can occur during bending can be minimized.

A plurality of alignment keys MK can be arranged between the first buffer layer 111a and the second buffer layer 111b. The plurality of alignment keys MK can be configured to identify the position of the pixel driving circuit PD during the fabricating process of the display device 1000. For example, the plurality of alignment keys MK can be configured to align the position of the pixel driving circuit PD transferred onto an adhesive layer 112. In another example, the plurality of alignment keys MK can be omitted.

The adhesive layer 112 can be positioned on the second buffer layer 111b. The adhesive layer 112 can be positioned in the display area AA, the first non-display area NA1, the bending area BA, and the second non-display area NA2. In another example, at least a portion of the adhesive layer 112 can be removed from the non-display area NA that includes the bending area BA. For example, the adhesive layer 112 can be made of any one of an adhesive polymer, epoxy resin, UV-curable resin, a polyimide-based material, an acrylate-based material, a urethane-based material, or polydimethylsiloxane (PDMS), but the example embodiments of the present disclosure are not limited thereto.

In the display area AA, the pixel driving circuit PD can be positioned on the adhesive layer 112. When the pixel driving circuit PD is implemented as a driving driver, the driving driver can be mounted on the adhesive layer 112 through a transfer process, but the example embodiments of the present disclosure are not limited thereto.

A first protective layer 113a and a second protective layer 113b can be positioned on the top or side surfaces of the adhesive layer 112 and the pixel driving circuit PD. The first protective layer 113a and the second protective layer 113b can be positioned to surround the side surface of the pixel driving circuit PD, but the example embodiments of the present disclosure are not limited thereto. For example, the second protective layer 113b can be positioned to cover at least a portion of the top surface of the pixel driving circuit PD. For example, at least one of the first protective layer 113a and the second protective layer 113b positioned in the bending area BA can be omitted.

For example, the first protective layer 113a can be entirely positioned over the display area AA and the non-display area NA, and the second protective layer 113b can be partially positioned over the display area AA, the first non-display area NA1, and the second non-display area NA2. For example, a portion of the second protective layer 113b in the bending area BA can be removed. However, the example embodiments of the present disclosure are not limited thereto.

The first protective layer 113a and the second protective layer 113b can be formed of an organic insulating material, but the example embodiments of the present disclosure are not limited thereto. For example, the first protective layer 113a and the second protective layer 113b can be formed of photoresist, polyimide (PI), or a photoacryl-based material, but the example embodiments of the present disclosure are not limited thereto. For example, the first protective layer 113a and the second protective layer 113b can be an overcoating layer or an insulating layer, but the example embodiments of the present disclosure are not limited thereto.

According to the present disclosure, a plurality of first connection wires 121 can be arranged on the second protective layer 113b in the display area AA. The plurality of first connection wires 121 can be wires for electrically connecting the pixel driving circuit PD to other components. For example, the pixel driving circuit PD can be electrically connected to the plurality of signal wires TL, the plurality of contact electrodes CCE, and the like through the plurality of first connection wires 121. For example, the plurality of first connection wires 121 can include a 1-1 connection wire 121a, a 1-2 connection wire 121b, a 1-3 connection wire 121c, and a first-fourth connection wire 121d, and the 1-1 connection wire 121a, the 1-2 connection wire 121b, the 1-3 connection wire 121c, and the first-fourth connection wire 121d can be electrically connected to each other through contact holes formed in insulating layers between the connection wires, but the example embodiments of the present disclosure are not limited thereto.

For example, a plurality of 1-1 connection wirings 121a can be disposed on the second protective layer 113b. A plurality of 1-1 connection wirings 121a can be electrically connected to the pixel driving circuit PD. A plurality of 1-1 connection wirings 121a can transfer voltages output from the pixel driving circuit PD to the first electrode CE1 or the second electrode CE2.

For example, the first and second protective layers 113a and 113b can be formed of an organic insulating material. For example, the first and second protective layers 113a and 113b can be formed of a photo resist, polyimide (PI), a photoacryl-based material, or the like, but example embodiments of the present disclosure are not limited thereto. For example, the first protective layer 113a and the second protective layer 113b can be formed of the same material. Example embodiments of the present disclosure are not limited thereto. For example, the first protective layer 113a and the second protective layer 113b can be insulating layers, but example embodiments of the present disclosure are not limited thereto.

In addition, the first insulating layer 114 can be disposed on the second protective layer 113b. For example, the first insulating layer 114 can be disposed in the entire display area AA and the non-display area NA. For example, the first insulating layer 114 can be formed of a single layer or multiple layers of silicon oxide (SiOx) or silicon nitride (SiNx), which is an inorganic film material, for example, the first insulating layer 114 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but example embodiments of the present disclosure are not limited thereto.

For example, as shown in FIG. 8, in order to prevent moisture permeation from penetrating from the non-display area NA, the first insulating layer 114 can be disposed only in the display area AA. disclosure The present is not limited thereto. A first organic insulating layer 115a can be disposed on the first insulating layer 114. The first organic insulating layer 115a can be formed of an organic insulating material, but example embodiments of the present disclosure are not limited thereto. For example, the first organic insulating layer 115a can be formed of a photo resist, polyimide (PI), a photoacryl-based material, or the like, but example embodiments of the present disclosure are not limited thereto.

In addition, a plurality of 1-2 connection wirings 121b can be disposed on the first organic insulating layer 115a. A plurality of 1-2 connection wirings 121b can be connected to or directly connected to the pixel driving circuit PD. For example, a portion of the 1-2 connection wiring 121b can be directly connected to the pixel driving circuit PD through a contact hole of the first insulating layer 114. Another portion of the 1-2 connection wiring 121b can be electrically connected to the 1-1 connection wiring 121a through a contact hole of the first insulating layer 114. However, example embodiments of the present disclosure are not limited thereto. The voltage output from the pixel driving circuit PD can be transferred to the first electrode CE1 or the second electrode CE2 through connection wirings different from a plurality of 1-2 connection wirings 121b.

The second organic insulating layer 115b can be positioned on the plurality of 1-2 connection wires 121b. The second organic insulating layer 115b can be entirely positioned over the display area AA and the non-display area NA, but the example embodiments of the present disclosure are not limited thereto. The second organic insulating layer 115b can be made of an organic insulating material, but the example embodiments of the present disclosure are not limited thereto. For example, the first organic insulating layer 115a can be made of photoresist, polyimide (PI), or a photoacryl-based material, but the example embodiments of the present disclosure are not limited thereto.

The plurality of 1-3 connection wires 121c can be positioned on the second organic insulating layer 115b. The plurality of 1-3 connection wires 121c can be electrically connected to the plurality of 1-2 connection wires 121b. For example, the 1-3 connection wire 121c can be electrically connected to the 1-2 connection wire 121b through a contact hole of the second organic insulating layer 115b.

A third organic insulating layer 115c can be positioned on the plurality of 1-3 connection wires 121c. The third organic insulating layer 115c can be positioned in a region excluding the bending area BA, but the example embodiments of the present disclosure are not limited thereto. The third organic insulating layer 115c can be positioned in the display area AA, the first non-display area NA1, and the second non-display area NA2, but the example embodiments of the present disclosure are not limited thereto. For example, a portion of the third organic insulating layer 115c positioned in the bending area BA can be removed. The third organic insulating layer 115c can be made of an organic insulating material, but the example embodiments of the present disclosure are not limited thereto. For example, the third organic insulating layer 115b can be made of photoresist, polyimide (PI), or a photoacryl-based material, but the example embodiments of the present disclosure are not limited thereto.

The plurality of first-fourth connection wires 121d can be positioned on the third organic insulating layer 115c. The plurality of first-fourth connection wires 121d can be electrically connected to the plurality of 1-3 connection wires 121c. For example, the first-fourth connection wire 121d can be electrically connected to the 1-3 connection wire 121c through a contact hole of the third insulating layer 115c.

A fourth organic insulating layer 115d can be disposed on a plurality of first to fourth connection wirings 121d. The fourth organic insulating layer 115d can be disposed in the remaining area except for the bending area BA, but example embodiments of the present disclosure are not limited thereto. The fourth organic insulating layer 115d can be disposed in the display area AA, the first non-display area NA1, and the second non-display area NA2, but example embodiments of the present disclosure are not limited thereto.

According to the present disclosure, a plurality of second connection wires 122 can be positioned on the second protective layer 113b in the non-display area NA. The plurality of second connection wires 122 can be wires for transmitting a signal, which has been transmitted to the pad portion PAD from the flexible circuit board (or flexible film) CB and the printed circuit board 160 (see FIG. 1), to the pixel driving circuit PD of the display area AA. For example, the plurality of second connection wires 122 can be electrically connected to the plurality of pad electrodes PE to receive a signal from the flexible circuit board (or flexible film) CB and the printed circuit board 160.

A plurality of 2-1 connection wirings 122a can be disposed on the second protective layer 113b. A plurality of 2-1 connection wirings 122a can extend from the second non-display area NA2 to the bending area BA and the first non-display area NA1. A plurality of 2-1 connection wirings 122a can transmit signals transmitted from the flexible circuit board (or flexible film) CB and the printed circuit board to the pad unit PAD to the pixel driving circuit PD of the display area AA.

A plurality of 2-2 connection wirings 122b can be disposed on the first insulating layer 114 and the first organic insulating layer 115a. A plurality of 2-2 connection wirings 122b can be disposed in the second non-display area NA2. The 2-2 connection wiring 122b can be electrically connected to the 2-1 connection wiring 122a through a contact hole of the first stopper layer 114. Accordingly, the signal from the flexible circuit board (or flexible film) CB and the printed circuit board can be transmitted to the 2-1 connection wiring 122a through the 2-2 connection wiring 122b.

A third organic insulating layer 115c can be disposed on the second organic insulating layer 115b and the 2-3 connection wiring 122c. Further, a 2-4 connection wiring 122d can be disposed on the third organic insulating layer 115c. The 2-4 connection wiring 122d can be disposed in the second non-display area NA2. The 2-4 connection wiring 122d can be electrically connected to the 2-3 connection wiring 122c through a contact hole of the third organic insulating layer 115c. Therefore, the signal from the flexible film FF and the printed circuit board can be transmitted to the 2-1 connection wiring 122a through the 2-4th connection wiring 122d, the 2-3th connection wiring 122c, and the 2-2 connection wiring 122b.

The plurality of first connection wires 121 and the plurality of second connection wires 122 can be formed of a highly flexible conductive material or any one of various conductive materials used in the display area AA.

For example, the second connection wiring 122 in which a part is disposed in the bending area BA can be made of a conductive material having excellent ductility, such as gold (Au), silver (Ag), or aluminum (Al), but example embodiments of the present disclosure are not limited thereto.

For another example, the plurality of first connection wires 121 and the plurality of second connection wires 122 can be made of molybdenum (Mo), chromium (Cr), titanium (Ti), nickel (Ni), neodymium (Nd), copper (Cu), an alloy of silver (Ag) and magnesium (Mg), or other alloys thereof, but the example embodiments of the present disclosure are not limited thereto.

The fourth organic insulating layer 115d can be positioned on the plurality of first connection wires 121 and the plurality of second connection wires 122. The fourth organic insulating layer 115d can be positioned in a region excluding the bending area BA, but the example embodiments of the present disclosure are not limited thereto. The fourth organic insulating layer 115d can be positioned in the display area AA, the first non-display area NA1, and the second non-display area NA2. A portion of the fourth organic insulating layer 115d in the bending area BA can be removed. The fourth organic insulating layer 115d can be made of an organic insulating material, but the example embodiments of the present disclosure are not limited thereto. For example, the fourth organic insulating layer 115d can be made of photoresist, polyimide (PI), or a photoacryl-based material, but the example embodiments of the present disclosure are not limited thereto.

Referring to FIG. 8, in the display area AA, the plurality of banks BNK can be positioned on the fourth organic insulating layer 115d. The plurality of banks BNK can respectively overlap the plurality of sub-pixels. One or more micro-LEDs ED that emit light of the same color can be positioned above each of the plurality of banks BNK.

A plurality of signal wires TL can be disposed on the fourth organic insulating layer 115d in the display area AA. A plurality of signal wires TL can be disposed in an area between a plurality of banks BNK. For example, a plurality of signal wires TL can be disposed adjacent to any one of a plurality of banks BNK.

The plurality of contact electrodes CCE can be positioned on the third insulating layer 115c in the display area AA. The plurality of contact electrodes CCE can supply the cathode voltage from the pixel driving circuit PD to the second electrode CE2.

The first electrode CE1 can be positioned on the bank BNK. For example, the first electrode CE1 can extend from an adjacent signal wire TL toward the top of the bank BNK. The first electrode CE1 can be positioned on the top and side surfaces of the bank BNK. For example, the first electrode CE1 can extend from the signal wire TL on the top surface of the third insulating layer 115c to the side surface of the bank BNK and to the top surface of the bank BNK.

Referring to FIGS. 8 and 9, the first electrode CE1 can be composed of a plurality of conductive layers. For example, the first electrode CE1 can include a first conductive layer CE1a, a second conductive layer CE1b, a third conductive layer CE1c, and a fourth conductive layer CE1d, but the example embodiments of the present disclosure are not limited thereto.

The first conductive layer CE1a can be positioned on the bank BNK. The second conductive layer CE1b can be positioned on the first conductive layer CE1a. The third conductive layer CE1c can be positioned on the second conductive layer CE1b. The fourth conductive layer CE1d can be positioned on the third conductive layer CE1c. For example, each of the first conductive layer CE1a, the second conductive layer CE1b, the third conductive layer CE1c, and the fourth conductive layer CE1d can be made of titanium (Ti), molybdenum (Mo), aluminum (Al), or titanium (Ti) and indium tin oxide (ITO), but the example embodiments of the present disclosure are not limited thereto.

According to the present disclosure, among the plurality of conductive layers constituting the first electrode CE1, some conductive layers with high reflection efficiency can be configured as an alignment key and/or a reflective plate for aligning the micro-LED ED.

For example, in order to configure the second conductive layer CE1b as a reflective plate, the third conductive layer CE1c and the fourth conductive layer CE1d covering the second conductive layer CE1b can be partially removed or etched. For example, portions of the third conductive layer CE1c and the fourth conductive layer CE1d positioned on the bank BNK can be removed or etched to expose the top surface of the second conductive layer CE1b. For example, in the third conductive layer CE1c and the fourth conductive layer CE1d, a central portion where the solder pattern SDP is positioned and a border portion (or edge portion) can be left, while the remaining portions can be removed. For example, the border portion (or edge portion) of each of the third conductive layer CE1c formed of titanium (Ti) and the fourth conductive layer CE1d formed of indium tin oxide (ITO) may not be etched. Accordingly, it is possible to prevent another conductive layer of the first electrode CE1 from being corroded by a tetramethylammonium hydroxide (TMAH) solution used in the masking process of the first electrode CE1.

According to the present disclosure, the first conductive layer CE1a and the third conductive layer CE1c can be made of titanium (Ti) or molybdenum (Mo). The second conductive layer CE1b can be made of aluminum (Al). The fourth conductive layer CE1d can include a transparent conductive oxide layer, such as indium tin oxide (ITO) or indium zinc oxide (IZO), which has good adhesion to the solder pattern SDP and exhibits corrosion resistance and acid resistance. However, the example embodiments of the present disclosure are not limited thereto.

The first conductive layer CE1a, the second conductive layer CE1b, the third conductive layer CE1c, and the fourth conductive layer CE1d can be sequentially deposited and then patterned by a photolithography process and an etching process, but example embodiments of the present disclosure are not limited thereto.

According to the present disclosure, the signal wire TL, the contact electrode CCE, and the pad electrode PE positioned in the same layer as the first electrode CE1 can be composed of multiple layers of a conductive material, but the example embodiments of the present disclosure are not limited thereto. For example, the signal wire TL, the contact electrode CCE, and the pad electrode PE can be formed of a multilayer of indium tin oxide (ITO)/titanium (Ti)/aluminum (Al)/titanium (Ti), but example embodiments of the present disclosure are not limited thereto.

According to the present disclosure, the solder pattern SDP can be positioned on the first electrode CE1 in each of the plurality of sub-pixels. The solder pattern SDP can bond the micro-LED ED to the first electrode CE1 to electrically connect the first electrode CE1 to the micro-LED ED. For example, the first electrode CE1 and the anode electrode 134 of the micro-LED ED can be electrically connected to each other through eutectic bonding using the solder pattern SDP, but the example embodiments of the present disclosure are not limited thereto. For example, when the solder pattern SDP be made of indium (In), and the anode electrode 134 of the micro-LED ED be made of gold (Au), the solder pattern SDP and the anode electrode 134 can be bonded by applying heat and pressure during the transfer process of the micro-LED ED. Through eutectic bonding, the micro-LED ED can be bonded to the solder pattern SDP and the first electrode CE1 without a separate adhesive material. For example, the solder pattern SDP can be made of indium (In), tin (Sn), or an alloy thereof, but the example embodiments of the present disclosure are not limited thereto. For example, the solder pattern SDP can be a bonding pad or a joining pad, but the example embodiments of the present disclosure are not limited thereto.

In addition, referring to FIG. 8, a second insulating layer 116 can be disposed on the fourth organic insulating layer 115d including the first electrode CE1 and a bank BNK. For example, the second insulating layer 116 can be disposed in the entire display area AA and the non-display area NA.

For example, in order to prevent moisture permeation penetrating from the non-display area NA, the second insulating layer 116 can be disposed only in the display area AA. The present disclosure is not limited thereto.

In addition, the second insulating layer 116 can be formed of a single layer or multiple layers of silicon oxide (SiOx) or silicon nitride (SiNx), which is an inorganic film material, for example, the lower insulating layer 116 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but example embodiments of the present disclosure are not limited thereto.

According to the present disclosure, the second insulating layer 116 serving as the passivation layer can be disposed on a plurality of signal wires TL, a plurality of first electrodes CE1, a plurality of contact electrodes CCE, and a third organic insulating layer 115c.

For example, the second insulating layer 116 can be positioned in the display area AA, the first non-display area NA1, and the second non-display area NA2. A portion of the second insulating layer 116 positioned in the bending area BA can be removed. In the second non-display area NA2, a portion of the second insulating layer 116 covering the plurality of pad electrodes PE can be removed. Since the second insulating layer 116 is positioned to cover the remaining regions other than the bending area BA and the regions where the plurality of pad electrodes PE and the solder pattern SDP are positioned, penetration of moisture or impurities into the micro-LED ED can be reduced. For example, the second insulating layer 116 can be composed of a single layer or multiple layers of silicon oxide (SiOx) or silicon nitride (SiNx), but the example embodiments of the present disclosure are not limited thereto.

In each of the plurality of sub-pixels, the micro-LED ED can be positioned on the solder pattern SDP. The first micro-LED 130 can be positioned in the first sub-pixel SP1. The second micro-LED 140 can be positioned in the second sub-pixel SP2. The third micro-LED 150 can be positioned in the third sub-pixel SP3.

The micro-LED ED can be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the example embodiments of the present disclosure are not limited thereto.

Referring to FIGS. 8 and 9, the first micro-LED 130 can include the anode electrode 134, a first semiconductor layer 131, an active layer 132, a second semiconductor layer 133, the cathode electrode 135, and an encapsulation film 136, but the example embodiments of the present disclosure are not limited thereto. For example, the first micro-LED 130 may not include the encapsulation film 136.

A first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be implemented as a compound semiconductor of a group III-V or a group II-VI and can be doped with an impurity (or dopant). For example, one of the first semiconductor layer 131 and the second semiconductor layer 133 can be a semiconductor layer doped with an n-type impurity, while the other can be a semiconductor layer doped with a p-type impurity, but the example embodiments of the present disclosure are not limited thereto. For example, at least one of the first semiconductor layer 131 and the second semiconductor layer 133 can be a layer in which an n-type or p-type impurity is doped into a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the example embodiments of the present disclosure are not limited thereto.

The active layer 132 can be positioned between the first semiconductor layer 131 and the second semiconductor layer 133. The active layer 132 can emit light by receiving holes and electrons from the first semiconductor layer 131 and the second semiconductor layer 133. For example, the active layer 132 can be configured in one of a single well structure, a multi-well structure, a single quantum well structure, a multi-quantum well (MQW) structure, a quantum dot structure, and a quantum wire structure, but the example embodiments of the present disclosure are not limited thereto. For example, the active layer 132 can be made of indium gallium nitride (InGaN) or gallium nitride (GaN), but the example embodiments of the present disclosure are not limited thereto.

For another example, the active layer 132 can include a well layer and a multi-quantum well (MQW) structure having a barrier layer having a band gap higher than that of the well layer. For example, the active layer 132 can include InGaN as a well layer and AlGaN layer as a barrier layer, but example embodiments of the present disclosure are not limited thereto.

The anode electrode 134 can be disposed between the first semiconductor layer 131 and the solder pattern SDP. For example, the anode electrode 134 can electrically connect the first semiconductor layer 131 to the first electrode CE1. The anode voltage output from the pixel driving circuit PD can be applied to the first semiconductor layer 131 through the signal wire TL, the first electrode CE1, and the anode electrode 134. For example, the anode electrode 134 can be formed of a conductive material capable of eutectic bonding with the solder pattern SDP. For example, the anode electrode 134 can be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the example embodiments of the present disclosure are not limited thereto.

The cathode electrode 135 can be positioned on the second semiconductor layer 133. For example, the cathode electrode 135 can electrically connect the second semiconductor layer 133 to the second electrode CE2. The cathode voltage outputted from the pixel driving circuit PD can be applied to the second semiconductor layer 133 through the contact electrode CCE, the second electrode CE2, and the cathode electrode 135. The cathode electrode 135 can be formed of a transparent conductive material such that light emitted from the micro-LED ED can be directed toward an upper side of the micro-LED ED, but the example embodiments of the present disclosure are not limited thereto. For example, the cathode electrode 135 can be formed of a material such as indium tin oxide (ITO), indium zinc oxide (IZO), or indium gallium zinc oxide (IGZO), but the example embodiments of the present disclosure are not limited thereto.

The encapsulation film 136 can be positioned on at least portions of the first semiconductor layer 131, the active layer 132, the second semiconductor layer 133, the anode electrode 134, and the cathode electrode 135. For example, the encapsulation film 136 can surround at least portions of the first semiconductor layer 131, the active layer 132, the second semiconductor layer 133, the anode electrode 134, and the cathode electrode 135.

For example, the encapsulation layer 136 can be disposed on at least a portion of the anode electrode 134 and the cathode electrode 135, for example, on the edge portion (or edge portion or one side) of the anode electrode 134 and the edge portion (or edge portion or one side) of the cathode electrode 135. At least a portion of the anode electrode 134 can be exposed from the encapsulation layer 136 to connect the anode electrode 134 and the solder pattern SDP. For example, at least a portion of the cathode electrode 135 can be exposed from the encapsulation layer 136 to connect the cathode electrode 135 and the second electrode CE2. For example, the encapsulation layer 136 can be formed of an insulating material such as silicon nitride (SiNx) or silicon oxide (SiOx), for example, the encapsulation film 136 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but example embodiments of the present disclosure are not limited thereto.

As another example, the encapsulation layer 136 can have a structure in which a reflective material is dispersed in a resin layer, but example embodiments of the present disclosure are not limited thereto. For example, the encapsulation layer 136 can be manufactured as a reflector having various structures, but example embodiments of the present disclosure are not limited thereto. Light emitted from the active layer 132 by the encapsulation layer 136 can be reflected upward to improve light extraction efficiency. For example, the encapsulation layer 136 can be a reflective layer, but example embodiments of the present disclosure are not limited thereto.

Although the light emitting device ED has been described as a vertical type structure according to the present disclosure, example embodiments of the present disclosure are not limited thereto. For example, the light emitting device ED can have a lateral STA structure or a flip chip STA structure.

Although the first light emitting device 130 has been described with reference to FIG. 9, the second light emitting device 140 and the third light emitting device 150 can have substantially the same structure as the first light emitting device 130. For example, the second light emitting device 140 and the third light emitting device 150 can be substantially the same as the first semiconductor layer 131, the active layer 132, the second semiconductor layer 133, the anode electrode 134, the cathode electrode 135, and the encapsulation film 136.

According to the present disclosure, a first optical layer 117a can be positioned on the second insulating layer 116 to surround the plurality of micro-LEDs ED in the display area AA. For example, the first optical layer 117a can be positioned to cover the plurality of micro-LEDs ED and the bank BNK in regions of the plurality of sub-pixels. For example, the first optical layer 117a can cover the bank BNK, a portion of the second insulating layer 116 and the spaces between the plurality of micro-LEDs ED. The first optical layer 117a can be positioned between the plurality of banks BNK and between the plurality of micro-LEDs ED included in one pixel PX, or can cover those spaces. For example, the first optical layer 117a can extend in a first direction X and can be separated in a second direction Y. For example, the first optical layer 117a can be positioned between the second insulating layer 116 and the second electrode CE2 to surround the side portions of the micro-LED ED and the bank BNK, but the example embodiments of the present disclosure are not limited thereto. For example, the first optical layer 117a can be a diffusion layer, a sidewall diffusion layer, or the like, but the example embodiments of the present disclosure are not limited thereto.

The first optical layer 117a can be formed of an organic insulating material in which fine particles are dispersed, but the example embodiments of the present disclosure are not limited thereto. For example, the first optical layer 117a can be made of siloxane in which fine metal particles such as titanium dioxide (TiO₂) particles are dispersed, but the example embodiments of the present disclosure are not limited thereto. Light from the plurality of micro-LEDs ED can be scattered by the fine particles dispersed in the first optical layer 117a and emitted to the outside of the display device 1000. Accordingly, the first optical layer 117a can improve the light extraction efficiency of the light emitted from the plurality of micro-LEDs ED.

For example, the first optical layer 117a can be positioned in each of the plurality of pixels PX, or can be commonly positioned in some of the pixels PX arranged in the same row, but the example embodiments of the present disclosure are not limited thereto. For example, the first optical layer 117a can be positioned in each of the plurality of pixels PX, or a single first optical layer 117a can be shared by the plurality of pixels PX. In another example, each of the plurality of sub-pixels can separately include the first optical layer 117a, but the example embodiments of the present disclosure are not limited thereto.

According to the present disclosure, the second optical layer 117b can be disposed on the second insulating layer 116 in the display area AA. For example, the second optical layer 117b can be disposed to surround the first optical layer 117a. For example, the second optical layer 117b can be in contact with the side surface of the first optical layer 117a. For example, the second optical layer 117b can be disposed in an area between a plurality of pixels PX. However, example embodiments of the present disclosure are not limited thereto, for example, the second optical layer 117b can be a diffusion layer, a diffusion layer window, a window diffusion layer, or the like, but example embodiments of the present disclosure are not limited thereto.

The second optical layer 117b can be formed of an organic insulating material, but example embodiments of the present disclosure are not limited thereto. The second optical layer 117b can be formed of the same material as the first optical layer 117a, but example embodiments of the present disclosure are not limited thereto. For example, the first optical layer 117a can include fine particles, and the second optical layer 117b may not include fine particles. For example, the second optical layer 117b can be formed of siloxane, but example embodiments of the present disclosure are not limited thereto.

For example, the thickness of the first optical layer 117a can be less than that of the second optical layer 117b, but example embodiments of the present disclosure are not limited thereto. Accordingly, when viewed in a plan view, the region in which the first optical layer 117a is disposed can include a concave portion recessed inwardly from the upper surface of the second optical layer 117b.

According to the present disclosure, the second electrode CE2 can be disposed on the first optical layer 117a and the second optical layer 117b. For example, the second electrode CE2 can be electrically connected to a plurality of contact electrodes CCE through a contact hole of the second optical layer 117b. For example, the second electrode CE2 can be disposed on a plurality of light emitting devices ED. For example, the second electrode CE2 can include a transparent conductive oxide such as indium tin oxide (ITO) or indium zinc oxide (IZO), but example embodiments of the present disclosure are not limited thereto. For example, the second electrode CE2 can be disposed to be in contact with the cathode electrode 135. For example, the second electrode CE2 can overlap the first optical layer 117a. For example, the outer plane of the first optical layer 117a can be covered. The second electrode CE2 can continuously extend in the first direction X of the substrate 110.

Accordingly, the substrate 110 can be commonly connected to a plurality of pixels PX arranged in the first direction X. For example, the second electrode CE2 can be commonly connected to a plurality of pixels PX.

According to the present disclosure, the second electrode CE2 can continuously extend on the first optical layer 117a, the second optical layer 117b, and the light emitting device ED. The region in which the first optical layer 117a is disposed can include a concave portion recessed inwardly from the upper surface of the second optical layer 117b. Accordingly, since the first portion of the second electrode CE2 disposed on the first optical layer 117a is disposed along the concave portion, the first portion can be disposed at a lower position than the second portion of the second electrode CE2 disposed on the second optical layer 117b.

In addition, the third insulating layer can be disposed on the second electrode CE2 and the first optical layer 117a. For example, the third insulating layer can be disposed in the entire display area AA and the non-display area NA. For example, the third insulating layer can be formed of a single layer or multiple layers of silicon oxide (SiOx) or silicon nitride (SiNx), which is an inorganic film material, but example embodiments of the present disclosure are not limited thereto.

For example, in order to prevent moisture permeation from penetrating from the non-display area NA, the third insulating layer can be disposed only in the display area AA. However, the present disclosure is not limited thereto.

The third optical layer 117c can be disposed to overlap a plurality of light emitting elements ED and the first optical layer 117a. Since the third optical layer 117c is disposed on the second electrode CE2 and a plurality of light emitting elements ED, a stain (Mura) that can occur in some of a plurality of light emitting elements ED can be improved. For example, when a plurality of light emitting elements ED are transferred onto the substrate 110 of the display device 1000, a region in which a gap between a plurality of light emitting elements ED is not uniform due to a process variation or the like can occur. When the spacing between the plurality of light emitting devices ED is non-uniform, the light emitting area of each of the plurality of light emitting devices ED can be non-uniformly disposed, and thus a stain (Mura) can be visually recognized by the user.

Accordingly, since the third optical layer 117c configured to uniformly diffuse light on the plurality of light emitting devices ED is configured, light emitted from some light emitting devices ED can be reduced from being visually recognized like a stain.

Therefore, since the light emitted from the plurality of light emitting devices ED is evenly diffused by the third optical layer 117c and extracted to the outside of the display device 1000, the luminance uniformity of the display device 1000 can be improved.

The third optical layer 117c can be formed of an organic insulating material in which fine particles are dispersed, but example embodiments of the present disclosure are not limited thereto. For example, the third optical layer 117c can be formed of siloxane in which fine metal particles such as titanium dioxide (TiO2) particles are dispersed, but example embodiments of the present disclosure are not limited thereto. For example, the third optical layer 117c can be formed of the same material as the first optical layer 117a, but example embodiments of the present disclosure are not limited thereto. For example, the third optical layer 117c can be a diffusion layer, an upper diffusion layer, or the like, but example embodiments of the present disclosure are not limited thereto.

According to the present disclosure, light from a plurality of light emitting devices ED can be scattered by fine particles dispersed in the third optical layer 117c and emitted to the outside of the display device 1000. The third optical layer 117c can evenly mix light emitted from a plurality of light emitting devices ED to further improve luminance uniformity of the display device 1000. In addition, light extraction efficiency of the display device 1000 can be improved by light scattered from a plurality of fine particles, and thus the display device 1000 can be driven at a low power.

In the display area AA, a black matrix BM can be disposed on the second electrode CE2, the first optical layer 117a, the second optical layer 117b, the third optical layer 117c, and the fourth stopper layer 118. For example, the black matrix BM can fill a contact hole of the second optical layer 117b. Since the black matrix BM is configured to cover the display area AA, color mixture and reflection of external light of a plurality of sub-pixels can be reduced. For example, since the black matrix BM is disposed within a contact hole in which the second electrode CE2 is connected with the contact electrode CCE, light leakage between a plurality of neighboring sub-pixels can be prevented.

For example, the black matrix BM can be formed of an opaque material, but example embodiments of the present disclosure are not limited thereto. For example, the black matrix BM can be an organic insulating material to which a black pigment or a black dye is added, for example, the black matrix BM can be formed of an organic layer such as an acryl-based material, an epoxy-based material, a phenolic-based material, a polyamide-based material, or a polyimide-based material, to which a black pigment or a black dye is added, but example embodiments of the present disclosure are not limited thereto.

In the display area AA, a cover layer 119 of FIG. 8 can be disposed on the black matrix BM. The cover layer 119 can protect an element under the third insulating layer, for example, the cover layer 119 can be formed of an organic insulating material, but example embodiments of the present disclosure are not limited thereto. For example, the cover layer 119 can be formed of a photo resist, polyimide (PI), a photo acryl-based material, or the like, but example embodiments of the present disclosure are not limited thereto. For example, the cover layer 119 can be an overcoating layer, an insulating layer, or the like, but example embodiments of the present disclosure are not limited thereto.

As shown in FIG. 1, the polarizing layer 293 can be disposed on the cover layer 119 via the first adhesive layer 291. The cover member 120 can be disposed on the polarizing layer 293 via the second adhesive layer 295. For example, the first adhesive layer 291 and the second adhesive layer 295 can include an optically clear adhesive (OCA), an optically clear resin (OCR), a pressure sensitive adhesive (PSA) or the like, but example embodiments of the present disclosure are not limited thereto.

According to the present disclosure, a plurality of pad electrodes PE can be disposed on the fourth organic insulating layer 115d in the second non-display area NA2. For example, at least portions of a plurality of pad electrodes PE can be exposed from the passivation layer 116. For example, a plurality of pad electrodes PE can be electrically connected to the 2-4th connection wiring 122d through a contact hole of the fourth organic insulating layer 115d.

An adhesive layer can be disposed on a plurality of pad electrodes PE. The adhesive layer can be an adhesive layer in which conductive balls are dispersed in an insulating material, but example embodiments of the present disclosure are not limited thereto. When heat or pressure is applied to the adhesive layer, the conductive balls can be electrically connected to a portion where heat or pressure is applied to have conductive characteristics. An adhesive layer can be disposed between a plurality of pad electrodes PE and a flexible circuit board (or a flexible film) CB to attach or bond a flexible circuit board (or a flexible film) CB to a plurality of pad electrodes PE. For example, the adhesive layer can be an anisotropic conductive film (ACF), but example embodiments of the present disclosure are not limited thereto.

A flexible circuit board (or a flexible film) CB can be disposed on the adhesive layer. The flexible circuit board (or a flexible film) CB can be electrically connected to a plurality of pad electrodes PE through an adhesive layer. Thus, the signals output from the flexible circuit board (or flexible film) CB and the printed circuit board can be transmitted to the pixel driving circuit PD of the display area AA through a plurality of pad electrodes PE, a 2-4 connection wiring 122d, a 2-3 connection wiring 122c, a 2-2 connection wiring 122b, and a 2-1 connection wiring 122a.

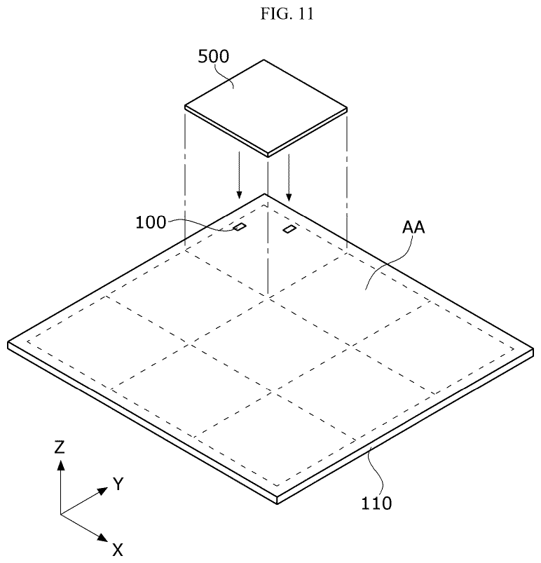

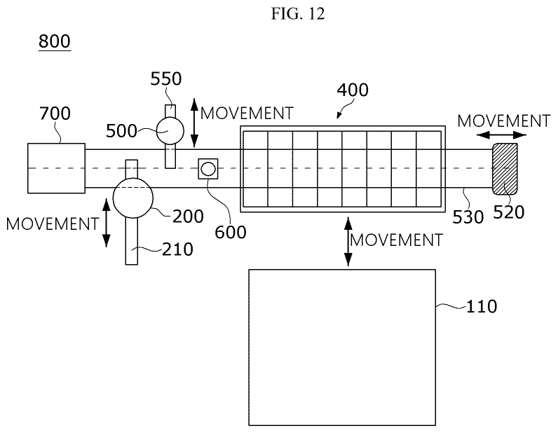

FIG. 10 is a perspective view illustrating a state in which a light-emitting element chip of a display device is picked up according to an example embodiment of the present disclosure. FIG. 11 is a perspective view illustrating a state in which the light-emitting element chip of the display device is transferred according to the example embodiment of the present disclosure.

Referring to FIGS. 10 and 11, to transfer a plurality of light-emitting element chips constituting a display device according to the example embodiment of the present disclosure, a wafer 200 having a plurality of light-emitting element chips 100, a light-emitting element transfer stamp 500 for picking up and transferring the plurality of light-emitting element chips 100, and a substrate 110 on which the plurality of light-emitting element chips 100 are transferred to constitute a display panel can be provided.

The wafer 200 can be used as a substrate for growing the light-emitting element chips 100, which is a light-emitting diode (LED) chip, and formed of any one selected from silicon (Si), sapphire (Al₂O₃), silicon carbide (SiC), gallium arsenide (GaAs), gallium nitride (GaN), gallium phosphide (GaP), indium phosphide (InP), zinc oxide (ZnO), spinel (MgAl₂O₄), magnesium oxide (MgO), lithium meta aluminate (LiAlO₂), aluminum nitride (AlN), and lithium gallate oxide (LiGaO₂), but is not limited thereto.

A plurality of micro light-emitting element chips 100 can be grown on the wafer 200. The light-emitting element chip 100 is a semiconductor element that emits light energy of various wavelengths by applying an electrical signal using the characteristics of a compound semiconductor. The light-emitting element chip 100 can be provided to have a small thickness of several micrometers.

A plurality of light-emitting element chips 100 can be disposed in parallel in one direction on the wafer 200. An interval between adjacent light-emitting element chips 100 can be set to have the minimum gap that is possible within a process. For example, to reduce a manufacturing cost of the wafer 200, it is preferable to integrate many light-emitting element chips 100 on the small wafer 200.

The light-emitting element transfer stamp 500 can be used as a transport means for transporting the plurality of light-emitting element chips 100 from the wafer 200 onto the substrate 110. The light-emitting element transfer stamp 500 can selectively pick up the plurality of light-emitting element chips 100 from the wafer 200. The light-emitting element transfer stamp 500 can selectively pick up the light-emitting element chips 100 at preset locations and transfer the light-emitting element chips 100 onto one-to-one corresponding pixels on the substrate 110.

The substrate 110 is a substrate that constitutes a display device, and a plurality of pixels can be arranged thereon. An area in which a plurality of pixels are disposed can be defined as a display area. At least one light-emitting element chip 100 can be ultimately assigned to each of the plurality of pixels. On the substrate 110, signal wires and electrodes for applying driving signals to the light-emitting element chips 100 can be arranged. When implemented in an active matrix (AM) manner, the substrate 110 can further include thin film transistors assigned to each pixel.

Referring to FIG. 11, the light-emitting element chips 100 transferred onto neighboring pixels can be arranged to be spaced a preset interval from each other. The interval between neighboring light-emitting element chips 100 among the light-emitting element chips 100 transferred onto the substrate 110 can be appropriately selected in consideration of display characteristics, element arrangement, etc. The substrate 110 can be provided to have a relatively larger size than the light-emitting element transfer stamp 500.

Specifically, a display area AA of the substrate 110 can be provided to have a greater area than the light-emitting element transfer stamp 500. In this case, to transfer the light-emitting element chips 100 to all pixels arranged in the display area AA, respectively, as illustrated in FIG. 11, it is necessary to repeatedly perform a plurality of pickup/transfer operations corresponding to a difference in area between the display area AA and the light-emitting element transfer stamp 500.

In addition, light-emitting element transfer processes using the light-emitting element transfer stamp 500, for example, a plurality of transfer processes, can be performed not only on the display area AA but also on a dummy area of the substrate 110, for example, a display non-operation area. The present example embodiment is not limited thereto.

FIG. 12 is a plan view illustrating a transfer device in the display device according to the example embodiment of the present disclosure.

Referring to FIG. 12, a transfer device 800 of the display device according to the example embodiment of the present disclosure can include a wafer loader 210 that loads the wafer 200, the stamp 500 that picks up a plurality of light-emitting element chips provided on the wafer 200, a stamp loader 550 that loads the stamp 500 to be mounted on a transfer head 520, and the transfer head 520 that moves the stamp 500 to be positioned on the wafer 200 to mount the plurality of light-emitting element chips by mounting the stamp 500 or moves the stamp 500 to be positioned on the substrate 110 to transfer the plurality of picked-up light-emitting element chips. The present example embodiment is not limited thereto.

In addition, the transfer device 800 can include an image detector 600 disposed at a predetermined distance below the stamp 500 to check whether there is a defective light-emitting element chip 100a among the plurality of light-emitting element chips 100 picked up from the wafer 200, and a chip removal system 700 that separates and removes the plurality of light-emitting element chips 100a and 100b picked up by the stamp 500 captured through the image detector 600 from the pickup unit 510 of the stamp 500. Here, the light-emitting element chip 100 can include a defective pickup chip 100a and a normal pickup chip 100b.

The transfer device 800 can include a substrate stage 400 on which the substrate 110 is loaded and positioned to transfer the plurality of light-emitting element chips 100 picked up by the stamp 500.

The wafer 200 can be moved forward by the wafer loader 210 while seated on the wafer loader 210 and positioned on a transfer rail 530 on which the transfer head 520 moves. In addition, the wafer 200 can be returned to its original location by the wafer loader 210 after the plurality of light-emitting element chips located on the wafer 200 are picked up by the stamp 500 while positioned on the transfer rail 530.

The stamp 500 can be mounted on the transfer head 520 while moved on the transfer rail 530 by the stamp loader 550. The stamp 500 mounted in this way can be moved by the transfer head 520 and positioned above the wafer 200 positioned on the transfer rail 530. In addition, the plurality of light-emitting element chips 100 located on the wafer 200 are picked up through a pickup unit 510 provided on a lower surface of the stamp 500.

In addition, the image detector 600 can be provided with a camera capable of capturing images of the plurality of light-emitting element chips 100 picked up by the pickup unit 510 provided on the lower surface of the stamp 500. The present example embodiment is not limited thereto. The image detector 600 can detect states of the plurality of light-emitting element chips 100 captured by the camera.

For example, the image detector 600 can detect the defective pickup chips 100a that are weakly attached to the pickup unit 510 by static electricity or are caught between the pickup units 510, and the normal pickup chips 100b that are normally picked up by the pickup unit 510 among the captured light-emitting element chips 100. In this way, through the capturing of the camera of the image detector 600, it can be identified whether the light-emitting element chips 100 picked up by the pickup unit 510 of the stamp 500 are the defective pickup chips 100a or the normal pickup chips 100b. In this case, when at least one of the picked up light-emitting element chips 100 is the defective light-emitting element chip 100a, all of the light-emitting element chips 100 picked up by the pickup unit 510 of the stamp 500 can be removed through a removing process of the chip removal system 700.

On the other hand, when there is no defective light-emitting element chip 100a among the picked up light-emitting element chips 100, it can be determined that all of the light-emitting element chips 100 picked up by the pickup unit 510 of the stamp 500 are the normal pickup chips 100b.

Accordingly, the transfer head 520 can directly move the stamp 500 to be positioned above the substrate 110 by the transfer head 520 without moving the stamp 500 to the chip removal system 700. The stamp 500 can transfer the normal pickup chips 100b picked up by the pickup unit 510 onto the substrate 110.

The transfer head 520 can locate the stamp 500 on the wafer 200 to pick up the plurality of light-emitting element chips 100 located on the wafer 200 by mounting the stamp 500 while moving back and forth on the transfer rail. In addition, the transfer head 520 can move the stamp 500 to be positioned above the substrate 110 so that the normal pickup chips 100b can be transferred onto the substrate 110 through the stamp 500 when the plurality of picked-up light-emitting element chips 100 are the normal pickup chips 100b.

Alternatively, the transfer head 520 can move the stamp 500 toward the chip removal system 700 to remove all of the defective pickup chips 100a and the normal pickup chips 100b picked up by the pickup unit 510 of the stamp 500 when some of the plurality of light-emitting element chips 100 picked up by the pickup unit 510 of the stamp 500 are the defective pickup chips 100a.

In addition, the transfer head 520 can move the stamp 500 to a location at which the image detector 600 is disposed to check whether the plurality of light-emitting element chips 100 are defective while the plurality of light-emitting element chips 100 are picked up from the wafer 200 by the pickup unit 510 of the stamp 500. If some defective pickup chips 100a present in the plurality of light-emitting element chips 100, the transfer head 520 can move the stamp 500 toward the chip removal system 700 to remove all of the defective pickup chips 100a and the normal pickup chips 100b picked up by the pickup unit 510 of the stamp 500, but not limited thereto.

The substrate 110 can be seated on the substrate stage 400 so that the plurality of pickup normal pickup chips 100b can be transferred onto the substrate 110 by the stamp 500. For example, the transfer head 520 can move the stamp 500 to a location at which the image detector 600 is disposed to check whether the plurality of light-emitting element chips 100 are defective while the plurality of light-emitting element chips 100 are picked up from the wafer 200 by the pickup unit 510 of the stamp 500. The transfer head 520 can move the stamp 500 to be positioned above the substrate 110 so that the normal pickup chips 100b can be transferred onto the substrate 110 through the stamp 500 when the plurality of picked-up light-emitting element chips 100 are all the normal pickup chips 100b.

In the transfer device 800, the stamp 500 can be loaded on the transfer rail 530 through the stamp loader 550 in a state in which the wafer 200 is loaded on the transfer rail 530 through the wafer loader 210. In addition, the transfer head 520 is moved to the position at which the wafer 200 is positioned while the stamp 500 loaded on the transfer rail 530 is mounted so that the stamp 500 is positioned on the wafer 200.

In addition, the stamp 500 picks up the plurality of light-emitting element chips 100 located on the wafer 200. The transfer head 520 moves the stamp 500 that picks up the plurality of light-emitting element chips 100 to the location at which the image detector 600 is located.

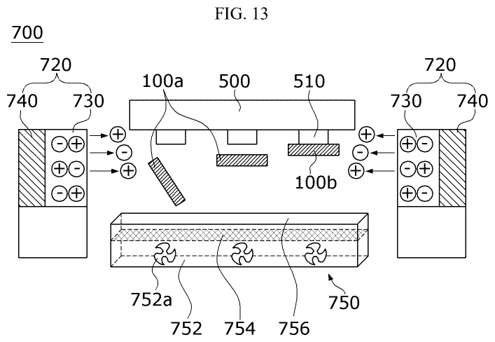

Referring to FIG. 12, the chip removal system 700 can output a plurality of ions toward the pickup unit 510 through a static electricity remover 720 (see FIG. 13). In this case, the plurality of ions are in contact with the pickup unit 510, which is a charged target object, to remove static electricity from the pickup unit 510 so that the plurality of defective pickup chips 100a and the plurality of normal pickup chips 100b attached to the pickup unit 510 with weak static electricity are separated from the pickup unit 510. In this way, not only the light-emitting element chips 100 attached to the plurality of pickup units 510 by static electricity, but also the light-emitting element chips 100 caught between the plurality of pickup units 510 or picked up in a misaligned manner can be separated from the pickup unit 510.

The chip removal system 700 can be provided with a light-emitting element chip collector 750 (see FIG. 13) to suction the light-emitting element chips 100 separated from the pickup unit 510, for example, the defective pickup chips 100a and the normal pickup chips 100b. For example, when some defective pickup chips 100a present in the plurality of light-emitting element chips 100, the transfer head 520 can move the stamp 500 toward the chip removal system 700, the light-emitting element chip collector 750 of chip removal system 700 can suction the light-emitting element chips 100 separated from the pickup unit 510, to remove all of the defective pickup chips 100a and the normal pickup chips 100b picked up by the pickup unit 510 of the stamp 500.

In addition, after the plurality of light-emitting element chips 100 are removed from the chip removal system 700, the transfer head 520 moves the stamp 500 to the location at which the wafer 200 is loaded on the transfer rail 530 in order to re-pick up the plurality of light-emitting element chips 100 located on the wafer 200.

The stamp 500 can re-pick up the plurality of light-emitting element chips 100 located on the wafer 200 through the pickup unit 510.

The image detector 600 can check whether the plurality of picked-up light-emitting element chips 100 are the defective pickup chips 100a or the normal pickup chips 100b.

In addition, when it is confirmed that the plurality of picked-up light-emitting element chips 100 are the normal pickup chips 100b, the stamp 500 can transfer the normal pickup chips 100b onto the substrate 110 by the transfer head 520, while moved to the location at which the substrate 110 is positioned.

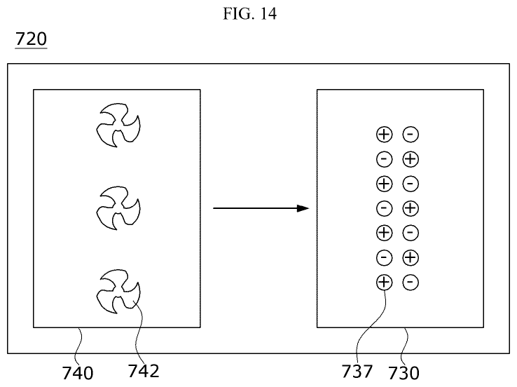

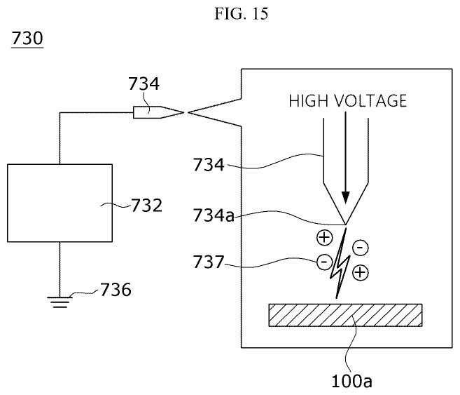

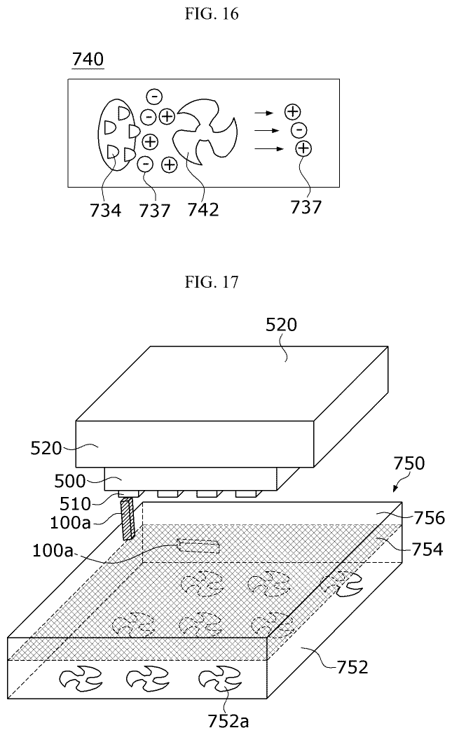

FIG. 13 is a cross-sectional view illustrating a chip removal system of the transfer device in the display device according to the example embodiment of the present disclosure. FIG. 14 is a view illustrating a static electricity remover of the chip removal system of the transfer device in the display device according to the example embodiment of the present disclosure. FIG. 15 is a view illustrating an ion generator of the static electricity remover of the chip removal system of the transfer device in the display device according to the example embodiment of the present disclosure. FIG. 16 is a view illustrating an ion generator of the static electricity remover of the chip removal system of the transfer device in the display device according to the example embodiment of the present disclosure.

Referring to FIG. 13, the chip removal system 700 according to the present disclosure can include at least one static electricity remover 720, and the light-emitting element chip collector 750 located between the static electricity removers 720 to suction and collect the light-emitting element chips 100, for example, the defective pickup chips 100a and the normal pickup chips 100b separated from the pickup unit 510 of the stamp 500. For example, when some defective pickup chips 100a present in the plurality of light-emitting element chips 100, the transfer head 520 can move the stamp 500 toward the chip removal system 700, the static electricity removers 720 and the light-emitting element chip collector 750 of chip removal system 700 can suction and collect the light-emitting element chips 100 separated from the pickup unit 510, to remove all of the defective pickup chips 100a and the normal pickup chips 100b picked up by the pickup unit 510 of the stamp 500. The present example embodiment is not limited thereto.

Referring to FIG. 14, the static electricity remover 720 can include an ion generator 730 and an ion blower 740 that blows ions 737 generated from the ion generator 730 toward the pickup unit 510 of the stamp 500. The present example embodiment is not limited thereto.

The static electricity remover 720 including the ion generator 730 and the ion blower 740 can be installed obliquely below the stamp 500, and the ions 737 blown from the static electricity remover 720 can be blown toward the entire surface of the stamp 500.

Referring to FIGS. 15 and 16, the ion generator 730 can include a high-voltage power supplier 732 and an electrode needle 734. The ion generator 730 applies a voltage to a tip 734a of an electrode needle 734 using the power of the high-voltage power supplier 732, and a weak discharge called corona discharge occurs. When the corona discharge occurs, air around the electrode needle 734 is changed to the ions 737.

The ions 737 generated in this way can remove static electricity by being in contact with the pickup unit 510 of the stamp 500, which is a charged target object. For example, when the ions 737 are moved toward the pickup unit 510 by a fan 742 in the ion blower 740, the static electricity that keeps the light-emitting element chips 100, for example, the defective pickup chips 100a and the normal pickup chips 100b in contact with the plurality of pickup units 510 can be removed so that the defective pickup chips 100a and the normal pickup chips 100b can be separated from the pickup unit 510.

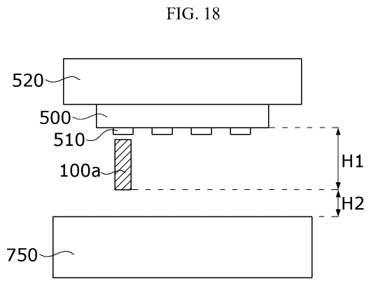

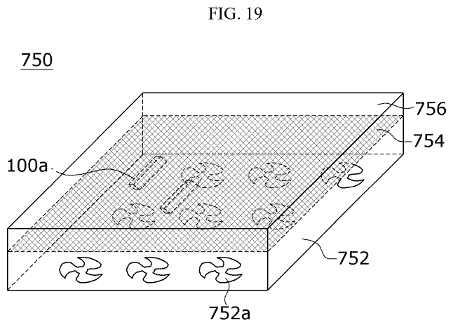

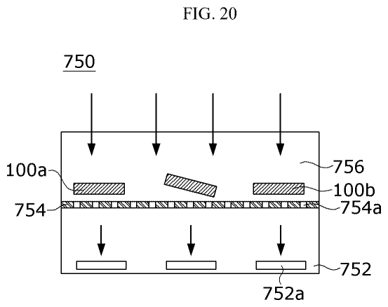

FIG. 17 is a perspective view illustrating a stamp and a light-emitting element chip collector of the chip removal system of the transfer device in the display device according to the example embodiment of the present disclosure. FIG. 18 is a cross-sectional view illustrating the light-emitting element chip collector of the chip removal system of the transfer device in the display device according to the example embodiment of the present disclosure. FIG. 19 is a perspective view illustrating a defective light-emitting element suction unit of the chip removal system of the transfer device in the display device according to the example embodiment of the present disclosure. FIG. 20 is a cross-sectional view illustrating a light-emitting element chip collector of the transfer device in the display device according to the example embodiment of the present disclosure.

Referring to FIGS. 17 to 20, the light-emitting element chip collector 750 according to the present disclosure can include an air suction unit 752 provided inside a lower portion thereof and having a predetermined empty space, a light-emitting element chip seating unit 754 disposed at a location that is vertically spaced a predetermined distance from the air suction unit 752, and a light-emitting element chip insertion unit 756 provided inside of an upper portion of the light-emitting element chip collector 750. The present example embodiment is not limited thereto.

The light-emitting element chip collector 750 can have a structure in which the light-emitting element chips 100, for example, the defective pickup chips 100a and the normal pickup chips 100b that are removed from the pickup unit 510 of the stamp 500 by the static electricity remover 720 of the chip removal system 700, are separated and collected.

In addition, the stamp 500 that picks up the plurality of light-emitting element chips 100 can be positioned above the light-emitting element chip collector 750.

Using the plurality of fans 752a in the air suction unit 752 of the light-emitting element chip collector 750, the pickup defective pickup chips 100a can be suctioned in a vacuum and safely dropped on the mesh-type light-emitting element chip seating unit 754 through the light-emitting element chip insertion unit 756. The present example embodiment is not limited thereto.

The light-emitting element chip collector 750 can have an equal or a greater area than the stamp 500. For example, the light-emitting element chip insertion unit 756 of the light-emitting element chip collector 750 can have an area that is the same as or greater than that of the stamp 500. For example, to effectively suction and collect the defective pickup chips 100a and the normal pickup chips 100b separated from the stamp 500 into the light-emitting element chip collector 750, the area of the light-emitting element chip insertion unit 756 of the light-emitting element chip collector 750 can be the same as or greater than that of the stamp 500. The present example embodiment is not limited thereto.

In addition, the plurality of fans 752a capable of suctioning air in the same manner as a vacuum cleaner can be provided in the air suction unit 752 of the light-emitting element chip collector 750.

The light-emitting element chip seating unit 754 can be formed to have a mesh structure and provided with holes smaller than the defective pickup chips 100a and the normal pickup chips 100b so that the defective pickup chips 100a and the normal pickup chips 100b can be separated from the stamp 500 and seated in the holes. For example, the light-emitting element chip seating unit 754 can be formed to have a mesh structure and provided with a plurality of holes each of which is smaller than each of the defective pickup chips 100a and the normal pickup chips 100b, so that each of the defective pickup chips 100a and the normal pickup chips 100b can be separated from the stamp 500 and seated in a corresponding hole of the plurality of holes, respectively. For example, when the defective pickup chips 100a and the normal pickup chips 100b pass through the light-emitting element chip seating unit 754 and fall into the air suction unit 752 below the light-emitting element chip seating unit 754, the suction function of the light-emitting element chip can be weakened due to the interference with the air suction operation of the air suction unit 752. Accordingly, the holes of the light-emitting element chip seating unit 754 can be formed to have a size corresponding to the light-emitting element chips 100 or a smaller size than the light-emitting element chips 100 so that the defective pickup chips 100a and the normal pickup chips 100b can be separated from the stamp 500 and seated on the light-emitting element chip seating unit 754. The present example embodiment is not limited thereto.

Referring to FIG. 18, a separation distance between the pickup unit 510 of the stamp 500 and the light-emitting element chip collector 750 can include the sum of a size H1 of the light-emitting element chips 100a and 100b and a distance H2 between the light-emitting element chips 100a and 100b and an upper end of the light-emitting element chip collector 750. A distance between the pickup unit 510 and the upper end of the light-emitting element chip collector 750 can be formed as the sum of the size H1 of the defective pickup chips 100a and the distance H2 of about 100 μm or more. However, the present example embodiment is not limited thereto. For example, a distance from a surface of the pickup unit 510 of the stamp 500 to the upper end of the non-contact light-emitting element chip collector 750 can be at least larger than each of the size H1 of the defective pickup chips 100a and the normal pickup chips 100b. The present example embodiment is not limited thereto. For example, a maximum safe distance between the pickup unit 510 and the light-emitting element chip collector 750 can be set only to be a distance in which it is easy to remove the defective pickup chip 100a. The present example embodiment is not limited thereto.

In addition, referring to FIGS. 17 to 20, the location of the light-emitting element chip removal system 700 can be preferably located at a location that is spaced a predetermined distance from the loader of the transfer device because foreign substances or defective chip fragments can be generated during ion blowing and collection of light-emitting element chips.

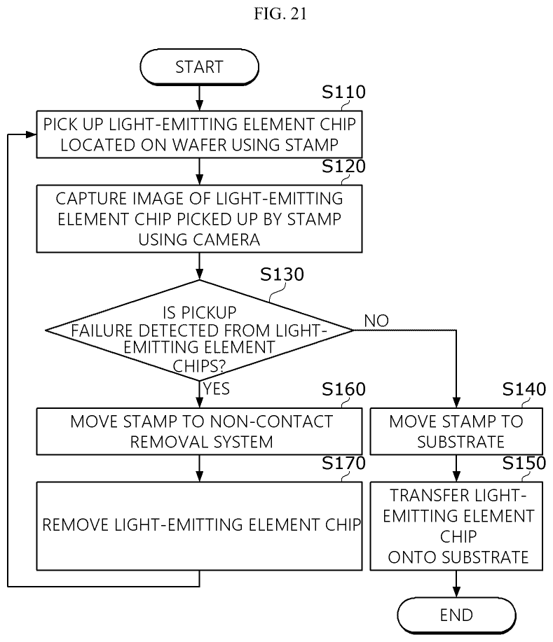

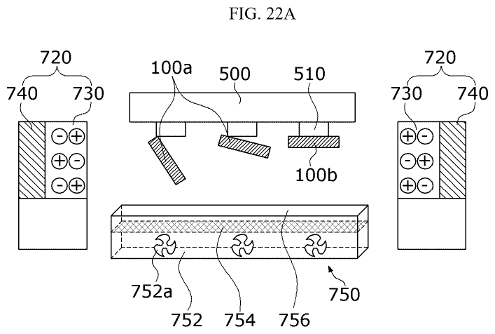

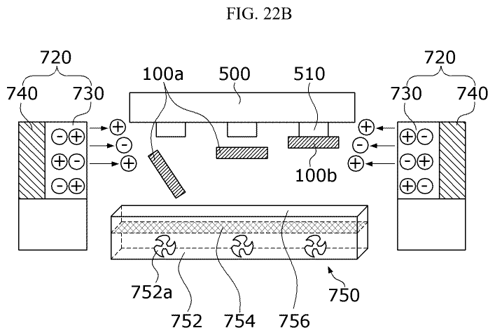

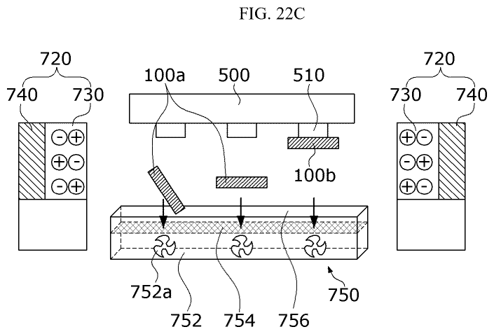

FIG. 21 is a flowchart illustrating a normal chip transfer process of the transfer device in the display device according to the example embodiment of the present disclosure. FIG. 22A, FIGS. 22B and 22C are cross-sectional views illustrating a defective chip removal process of the transfer device in the display device according to the example embodiment of the present disclosure.

Referring to FIG. 21, as a first operation S110, the wafer 200 can be positioned on the transfer rail 530, on which the transfer head 520 is moved forward, by the wafer loader 210 while seated on the wafer loader 210.

Next, the wafer 200 can be returned to its original location by the wafer loader 210, after the plurality of light-emitting element chips located on the wafer 200 are picked up by the stamp 500, while the wafer 200 being positioned on the transfer rail 530.

Subsequently, the stamp 500 can be mounted on the transfer head 520, after being moved on the transfer rail 530 while seated on the stamp loader 550.

Next, the stamp 500 mounted on the transfer head 520 can be moved by the transfer head 520 and positioned above the wafer 200 located on the transfer rail 530.

In this case, the transfer head 520 can locate the stamp 500 on the wafer 200 so that the stamp 500 is mounted to pick up the plurality of light-emitting element chips 100 located on the wafer 200 while moving back and forth on the transfer rail 530 or locate the stamp 500 above the substrate 110 so that the plurality of picked-up light-emitting element chips 100 can be transferred onto the substrate 110 through the stamp 500 when being the normal pickup chips 100b. The present example embodiment is not limited thereto.

Subsequently, the pickup unit 510 provided on the lower surface of the stamp 500 can pick up the plurality of light-emitting element chips 100 located on the wafer 200.

Next, after picking up the plurality of light-emitting element chips 100, the transfer head 520 can move the stamp 500 to the location at which the image detector 600 is located.

Subsequently, as a second operation S120, the image detector 600 can use a camera to capture images of the plurality of light-emitting element chips 100 picked up by the pickup unit 510 provided on the lower surface of the stamp 500. At this time, the image detector 600 can check an adhered state of the plurality of light-emitting element chips 100 captured by the camera.

Next, as a third operation S130, the image detector 600 can detect whether the pickup defective chips 100a are weakly attached to the pickup unit 510 or caught between the pickup units 510, due to static electricity among the plurality of captured light-emitting element chips 100, and whether the normal pickup chips 100b normally picked up by the pickup unit 510 are present.

Subsequently, when the light-emitting element chips picked up by the pickup unit 510 of the stamp 500 are confirmed to be the normal pickup chips 100b through the analysis of the image detector 600, as provided in a fourth operation S140, the transfer head 520 can move the stamp 500 toward the substrate stage 400 on which the substrate 110 is loaded without moving the stamp 500 toward the chip removal system 700.

Next, as a fifth operation S150, the transfer process of the normal pickup chips 100b is completed by transferring the plurality of normal pickup chips 100b picked up by the pickup unit 510 onto the transfer locations of the substrate 110, respectively. For example, the substrate 110 can be seated on the substrate stage 400 so that the plurality of pickup normal pickup chips 100b can be transferred onto the substrate 110 by the stamp 500. For example, the transfer head 520 can move the stamp 500 to a location at which the image detector 600 is disposed to check whether the plurality of light-emitting element chips 100 are defective while the plurality of light-emitting element chips 100 are picked up from the wafer 200 by the pickup unit 510 of the stamp 500. The transfer head 520 can move the stamp 500 to be positioned above the substrate 110 so that the normal pickup chips 100b can be transferred onto the substrate 110 through the stamp 500 when the plurality of picked-up light-emitting element chips 100 are all the normal pickup chips 100b.

On the other hand, referring to the third operation S130 and FIG. 22A, in a six operation S160, when some of the light-emitting element chips 100 picked up by the pickup unit 510 of the stamp 500 are confirmed to be the defective pickup chips 100a through the image detector 600, the transfer head 520 can move the stamp 500 toward the non-contact chip removal system 700.

Subsequently, the transfer head 520 can locate the stamp 500 above the chip removal system 700.

Next, referring to a seventh operation S170 and FIG. 22B, the chip removal system 700 can blow the plurality of ions 737 toward a side surface of the pickup unit 510 provided on the stamp 500 through the static electricity remover 720 and separate and remove the defective pickup chips 100a and the normal pickup chips 100b from the pickup unit 510. For example, the transfer head 520 can move the stamp 500 to a location at which the image detector 600 is disposed to check whether the plurality of light-emitting element chips 100 are defective while the plurality of light-emitting element chips 100 are picked up from the wafer 200 by the pickup unit 510 of the stamp 500. If some defective pickup chips 100a present in the plurality of light-emitting element chips 100, the transfer head 520 can move the stamp 500 toward the chip removal system 700 to remove all of the defective pickup chips 100a and the normal pickup chips 100b picked up by the pickup unit 510 of the stamp 500. In this case, since the plurality of ions 737 are in contact with the pickup unit 510, which is a charged target object, to remove the static electricity of the pickup unit 510, not only the plurality of defective pickup chips 100a but also the plurality of normal pickup chips 100b attached to the pickup unit 510 due to the weak static electricity are separated from the pickup unit 510.

In this way, the plurality of defective pickup chips 100a attached to the pickup unit 510 due to static electricity and the normal pickup chips 100b are separated, and the defective pickup chips 100a and the normal pickup chips 100b are not present in the pickup unit 510.

In this case, referring to FIG. 22C, since the chip removal system 700 can be provided with the light-emitting element chip collector 750, the defective pickup chips 100a and the normal pickup chips 100b separated from the pickup unit 510 can be suctioned and collected.

The light-emitting element chip collector 750 can include the air suction unit 752 having a predetermined empty space, the mesh-type light-emitting element chip seating unit 754 located at a location that is vertically spaced a predetermined distance from the air suction unit 752, and the light-emitting element chip insertion unit 756 on which the defective pickup chips 100a and the normal pickup chips 100b fall. The present example embodiment is not limited thereto.

The light-emitting element chip collector 750 can have a structure in which the light-emitting element chips are separated and collected from the pickup unit 510 of the stamp 500 by the static electricity remover 720 of the chip removal system 700.

In this case, using the plurality of fans 752a in the air suction unit 752 of the light-emitting element chip collector 750, the light-emitting element chips 100a and 100b can be suctioned in a vacuum to safely fall on the mesh-type light-emitting element chip seating unit 754 through the light-emitting element chip insertion unit 756. The present example embodiment is not limited thereto.

The light-emitting element chip collector 750 can have an equal or a greater area than the stamp 500. For example, the light-emitting element chip insertion unit 756 of the light-emitting element chip collector 750 can have an area that is the same as or greater than that of the stamp 500. For example, to effectively suction and collect the defective pickup chips 100a and the normal pickup chips 100b separated from the stamp 500 into the light-emitting element chip collector 750, the area of the light-emitting element chip insertion unit 756 of the light-emitting element chip collector 750 can be the same as or greater than that of the stamp 500. The present example embodiment is not limited thereto.

The light-emitting element chip seating unit 754 can be formed to have a mesh structure and provided with holes smaller than the defective pickup chips 100a and the normal pickup chips 100b so that the defective pickup chips 100a and the normal pickup chips 100b can be separated from the stamp 500 and seated in the holes. For example, the light-emitting element chip seating unit 754 can be formed to have a mesh structure and provided with a plurality of holes each of which is smaller than each of the defective pickup chips 100a and the normal pickup chips 100b, so that each of the defective pickup chips 100a and the normal pickup chips 100b can be separated from the stamp 500 and seated in a corresponding hole of the plurality of holes, respectively. For example, when the light-emitting element chips 100 pass through the light-emitting element chip seating unit 754 and fall into the air suction unit 752 below the light-emitting element chip seating unit 754, the suction function of the defective pickup chips 100a and the normal pickup chips 100b cannot be effectively performed due to the interference by the air suction operation of the air suction unit 752.

Accordingly, the holes of the light-emitting element chip seating unit 754 can be formed to have a size corresponding to the defective pickup chips 100a and the normal pickup chips 100b or a smaller size than the defective pickup chips 100a and the normal pickup chips 100b so that the defective pickup chips 100a and the normal pickup chips 100b can be separated from the stamp 500 and seated on the light-emitting element chip seating unit 754. The present example embodiment is not limited thereto.

Subsequently, in the seventh operation S170, after the plurality of light-emitting element chips 100a and 100b are removed from the chip removal system 700, the transfer head 520 moves the stamp 500 toward the transfer rail 530 on which the wafer 200 is loaded, and the process of the first operation S110 is performed again.

For example, in a state in which the stamp 500 is positioned above the loaded wafer 200, the pickup unit 510 provided on the lower surface of the stamp 500 can pick up the plurality of light-emitting element chips 100a and 100b located on the wafer 200 again.

Next, after picking up the plurality of light-emitting element chips 100, the transfer head 520 can move the stamp 500 to the location at which the image detector 600 is located.

Subsequently, referring to the second operation S120, the image detector 600 can use a camera to capture images of the plurality of light-emitting element chips 100a and 100b picked up by the pickup unit 510 provided on the lower surface of the stamp 500. In this case, the image detector 600 can check an adhered state of the plurality of light-emitting element chips 100a and 100b captured by the camera.

Next, referring to the third operation S130, the image detector 600 can detect whether the defective pickup chips 100a are weakly attached to the pickup unit 510 or caught between the pickup units 510 due to static electricity among the plurality of captured light-emitting element chips 100a and 100b and whether the normal pickup chips 100b normally picked up by the pickup unit 510 are present.

Subsequently, when the light-emitting element chips picked up by the pickup unit 510 of the stamp 500 are confirmed to be the normal pickup chips 100b through the analysis of the image detector 600, as provided in a fourth operation S140, the transfer head 520 can move the stamp 500 toward the substrate stage 400 on which the substrate 110 is loaded without moving the stamp 500 toward the chip removal system 700.

Next, as provided in the fifth operation S150, the transfer process of the normal pickup chips 100b is completed by transferring the plurality of normal pickup chips 100b picked up by the pickup unit 510 of the stamp 500 onto the transfer locations of the substrate 110, respectively.

The transfer device and the pickup control method for a light-emitting element chip can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more example embodiments of the present disclosure can be applied to an organic light emitting lighting device or an inorganic light emitting lighting device.

In this way, according to the present disclosure, by installing a non-contact chip removal system to remove defective chips in a light-emitting element transfer device, it is possible to reduce the probability of damage to a stamp and increase the use time of the stamp, thereby shortening the time for unnecessarily replacing stamps.

According to the present disclosure, even when a camera incorrectly detects a light-emitting element chip picked up by a pickup part of a stamp, it is possible to reduce the probability of damage to components of the stamp using the non-contact chip removal system.

According to the present disclosure, by installing a non-contact chip removal system in a light-emitting element transfer device to remove a light-emitting element chip, it is possible to reduce the probability of damage to a stamp and increase the use time of the stamp, thereby shortening the time for unnecessarily replacing stamps.

According to the present disclosure, even when a camera incorrectly detects a light-emitting element chip picked up by a pickup part of a stamp, it is possible to reduce the probability of damage to components of the stamp using the non-contact chip removal system.

Effects of the present disclosure are not limited to the above-described effects, and other effects that are not mentioned will be able to be clearly understood by those skilled in the art to which the present disclosure pertains from the following description.

The transfer device and the pickup control method for a light-emitting element chip according to various example embodiments of the present disclosure can be described as follows.

A pickup control method for a light-emitting element chip according to various example embodiments of the present disclosure can comprise a first operation of loading a plurality of stamps on a transfer head, transporting the transfer head to a first substrate, and picking up a plurality of light-emitting element chips with the stamps; a second operation of transporting the transfer head along with the stamps that pick up the light-emitting element chips to a second substrate and checking pickup states of the light-emitting element chips transported to the second substrate using an image detector located below the transfer head; a third operation of transporting the transfer head along with the stamps that pick up the light-emitting element chips toward a chip removal system when a pickup failure is detected from the light-emitting element chips as a result of analyzing an image captured by the image detector; and a fourth operation of blowing ionized air toward the stamps from the chip removal system and removing the light-emitting element chips from the stamps in a non-contact manner.

According to one example embodiment of the present disclosure, the pickup control method can further include a fifth operation of transferring the light-emitting element chips onto the second substrate when the pickup failure is not detected from the light-emitting element chips in the third operation.

According to one example embodiment of the present disclosure, the pickup control method can further include performing the first to fifth operations by transporting the transfer head along with the stamps from which the light-emitting element chips are removed back to the first substrate in the fourth operation.

According to one example embodiment of the present disclosure, the fourth operation of removing the light-emitting element chips in the non-contact manner can include moving the stamps that pick up the plurality of light-emitting element chips to be positioned above the chip removal system; blowing ionized ions generated by a static electricity remover of the chip removal system toward a pickup unit of each of the stamps and removing static electricity of the plurality of light-emitting element chips picked up by the pickup unit; and suctioning, by a light-emitting element chip collector, the plurality of light-emitting element chips separated by the static electricity removal of the plurality of light-emitting element chips.

According to one example embodiment of the present disclosure, the blowing of the ionized ions generated by the static electricity remover of the chip removal system toward the pickup unit of each of the stamps can further include generating, by an ion generator of the static electricity remover, a plurality of ionized ions; and blowing the plurality of ionized ions toward the pickup unit of each of the stamps using a fan of an ion blower.

According to one example embodiment of the present disclosure, the generating, by an ion generator of the static electricity remover, a plurality of ionized ions includes: applying, by the ion generator a voltage to a tip of an electrode needle using a power of a high-voltage power supplier, such that an air around the electrode needle is changed to the plurality of ionized ions.

According to one example embodiment of the present disclosure, the fifth operation of transferring the light-emitting element chips onto the second substrate when the pickup failure can be not detected from the light-emitting element chips in the third operation further includes transferring the plurality of light-emitting element chips picked up by the pickup unit of each of the stamps onto transfer locations of the second substrate using the transfer head in a state in which the stamps that pick up the plurality of light-emitting element chips are moved to the second substrate.

According to one example embodiment of the present disclosure, the image detector includes a camera.

A transfer device according to various example embodiments of the present disclosure can comprise a stamp that picks up a plurality of light-emitting element chips located on a first substrate and transfers the plurality of light-emitting element chips onto a second substrate; a transfer head that transports the stamp to perform transferring and picking up; an image detector that checks pickup states of the plurality of picked-up light-emitting element chips; and a chip removal system that removes the light-emitting element chips when a pickup failure is detected from the light-emitting element chips.

According to one example embodiment of the present disclosure, the transfer device further comprises a stamp loader configured to load the stamp to be mounted on the transfer head.

According to one example embodiment of the present disclosure, the transfer device further comprises a transfer rail, on which the stamp loader loads and the transfer head moves.

According to one example embodiment of the present disclosure, the image detector can include a camera.

According to one example embodiment of the present disclosure, the chip removal system can include at least one static electricity remover and a light-emitting element chip collector that is located below the stamp and suctions light-emitting element chips separated from the pickup unit of the stamp.

According to one example embodiment of the present disclosure, the static electricity remover can include an ion generator and an ion blower that blows ionized ions output from the ion generator toward the pickup unit of the stamp.

According to one example embodiment of the present disclosure, the ion generator can include a high-voltage power supply unit and an electrode chip.

According to one example embodiment of the present disclosure, the ion blower can include a plurality of fans.

According to one example embodiment of the present disclosure, the light-emitting element chip collector can include an air suction unit, a light-emitting element chip seating unit, and a light-emitting element chip insertion unit.

According to one example embodiment of the present disclosure, the light-emitting element chip collector can have a greater area than the stamp or has a same area as the stamp.

According to one example embodiment of the present disclosure, a separation distance between the pickup unit of the stamp and the light-emitting element chip collector can be equal to a sum of a size of a pickup defective chip and a distance between an end of the pickup defective chip and an upper end of the light-emitting element chip collector.

According to one example embodiment of the present disclosure, the distance between the end of the pickup defective chip and the upper end of the light-emitting element chip collector can be 100 μm or more.

According to one example embodiment of the present disclosure, the light-emitting element chip seating unit of the light-emitting element chip collector can include a mesh type light-emitting element chip seating unit.

According to one example embodiment of the present disclosure, the plurality of light-emitting element chips removed from the stamp on the chip removal system can be seated on the light-emitting element chip seating unit.

According to one example embodiment of the present disclosure, the light-emitting element chip seating unit includes holes corresponding to the light-emitting element chips.

According to one example embodiment of the present disclosure, a size of each hole is smaller than a size of each of the light-emitting element chips, and the light-emitting element chips could be separated from the stamp and seated in the holes.

According to one example embodiment of the present disclosure, the air suction unit can include a plurality of fans.

Although example embodiments of the present disclosure have been described in more detail with reference to the accompanying drawings, the present disclosure is not necessarily limited to the example embodiments, and various modifications can be carried out without departing from the technical spirit of the present disclosure.

Therefore, the example embodiments disclosed in the present disclosure are not intended to limited the technical spirit of the present disclosure, but intended to describe the same, and the scope of the technical spirit of the present disclosure is not limited by these example embodiments. Therefore, it should be understood that the above-described example embodiments are illustrative and not restrictive in all respects.

What is claimed is:

1. A pickup control method for a light-emitting element chip, the method comprising:
a first operation of loading stamps on a transfer head, transporting the transfer head to a first substrate, and picking up light-emitting element chips using the stamps;
a second operation of transporting the transfer head along with the stamps that were used to pick up the light-emitting element chips to a second substrate, and checking pickup states of the light-emitting element chips transported to the second substrate using an image detector located below the transfer head;
a third operation of transporting the transfer head along with the stamps that were used to pick up the light-emitting element chips toward a chip removal system when a pickup failure is detected from the light-emitting element chips as a result of analyzing an image captured by the image detector; and
a fourth operation of directing ionized air toward the stamps from the chip removal system, and removing the light-emitting element chips from the stamps in a non-contact manner.

2. The pickup control method of claim 1, further comprising a fifth operation of transferring the light-emitting element chips onto the second substrate when the pickup failure is not detected from the light-emitting element chips in the third operation.

3. The pickup control method of claim 2, further comprising performing the first to fifth operations by transporting the transfer head along with the stamps from which the light-emitting element chips are removed back to the first substrate in the fourth operation.

4. The pickup control method of claim 1, wherein the fourth operation of removing the light-emitting element chips in the non-contact manner includes:
moving the stamps that were used to pick up the light-emitting element chips to be positioned above the chip removal system;
blowing ionized ions generated by a static electricity remover of the chip removal system toward a pickup unit of each of the stamps, and removing static electricity of the light-emitting element chips picked up by the pickup unit; and
suctioning, by a light-emitting element chip collector, the light-emitting element chips separated by the static electricity removal of the light-emitting element chips.

5. The pickup control method of claim 4, wherein the blowing of the ionized ions generated by the static electricity remover of the chip removal system toward the pickup unit of each of the stamps further includes:
generating, by an ion generator of the static electricity remover, a plurality of ionized ions; and
blowing the plurality of ionized ions toward the pickup unit of each of the stamps using a fan of an ion blower.

6. The pickup control method of claim 5, wherein the the generating the plurality of ionized ions includes:
applying, by the ion generator, a voltage to a tip of an electrode needle using a power of a high-voltage power supplier, so that an air around the electrode needle is changed to the plurality of ionized ions.

7. The pickup control method of claim 2, wherein the fifth operation of transferring the light-emitting element chips onto the second substrate when the pickup failure is not detected from the light-emitting element chips in the third operation includes:
transferring the light-emitting element chips picked up by the pickup unit of each of the stamps onto transfer locations of the second substrate using the transfer head in a state in which the stamps that were used to pick up the light-emitting element chips are moved to the second substrate.

8. The transfer device of claim 1, wherein the image detector includes a camera.

9. A transfer device comprising:
a stamp that picks up light-emitting element chips located on a first substrate and transfers the light-emitting element chips onto a second substrate;
a transfer head that transports the stamp to perform the transferring and picking up;
an image detector that checks pickup states of the picked-up light-emitting element chips; and
a chip removal system that removes the light-emitting element chips when a pickup failure is detected from the light-emitting element chips.

10. The transfer device of claim 9, further comprising a stamp loader configured to load the stamp to be mounted on the transfer head and a transfer rail, on which the stamp loader loads and the transfer head moves.

11. The transfer device of claim 9, wherein the image detector includes a camera.

12. The transfer device of claim 9, wherein the chip removal system includes at least one static electricity remover and a light-emitting element chip collector that is located below the stamp and suctions light-emitting element chips separated from a pickup unit of the stamp.

13. The transfer device of claim 12, wherein the at least one static electricity remover includes an ion generator and an ion blower that blows ionized ions output from the ion generator toward the pickup unit of the stamp, and
wherein the ion generator includes a high-voltage power supply unit and an electrode chip, and the ion blower includes fans.

14. The transfer device of claim 12, wherein the light-emitting element chip collector includes an air suction unit, a light-emitting element chip seating unit, and a light-emitting element chip insertion unit, and
wherein the air suction unit includes fans.

15. The transfer device of claim 14, wherein the light-emitting element chip collector has a greater area than the stamp or has a same area as the stamp, and
wherein the light-emitting element chip seating unit of the light-emitting element chip collector is a mesh type light-emitting element chip seating unit.

16. The transfer device of claim 14, wherein a separation distance between the pickup unit of the stamp and the light-emitting element chip collector is equal to a sum of a size of a pickup defective chip and a distance between an end of the pickup defective chip and an upper end of the light-emitting element chip collector.

17. The transfer device of claim 16, wherein the distance between the end of the pickup defective chip and the upper end of the light-emitting element chip collector is 100 μm or more.

18. The transfer device of claim 14, wherein the light-emitting element chips removed from the stamp on the chip removal system are seated on the light-emitting element chip seating unit.

19. The transfer device of claim 18, wherein the light-emitting element chip seating unit includes holes corresponding to the light-emitting element chips.

20. The transfer device of claim 19, wherein a size of each of the holes of the light-emitting element chip seating unit is smaller than a size of each of the light-emitting element chips, and
wherein the light-emitting element chips are separated from the stamp and seated in the holes.
